(19) United States
(12) Patent Application Publication
(10) Pub. No.: US 2026/0356658 A1
(43) Pub. Date: Nov. 12, 2026

(54) SUSPENSION SYSTEM FOR TWO-DIMENSIONAL MICROELECTROMECHANICAL SYSTEM MIRROR SCANNER FOR REDUCED MECHANICAL STRESS

(71) Applicant: Infineon Technologies AG, Neubiberg (DE)

(72) Inventors: Malika BELLA, Ottobrunn (DE); Theresa LUTZ, Göttingen (DE); Stephan Gerhard ALBERT, München (DE)

(21) Appl. No.: 19/199,921

(22) Filed: May 6, 2025

(51) Int. Cl. B81B 3/00; G02B 26/08; G02B 26/10

(52) U.S. Cl. CPC B81B 3/0072; G02B 26/0858; G02B 26/105; B81B 2201/042; B81B 2203/0154; B81B 2203/0307; B81B 2203/058; B81B 2207/01

(57) ABSTRACT

A suspension assembly for a MEMS mirror includes a plurality of torsion beams and a plurality of suspension beams that are attached to a fixed frame and a mirror body of the MEMS mirror. The MEMS mirror may be driven about two rotation axes at respective oscillation frequencies such that a fixed frequency ratio between the oscillation frequencies is achieved. The suspension assembly may include four pairs of suspension beams connecting the mirror body to the fixed frame. The four pairs of suspension beams may enable tuning of the oscillation frequencies to a desired fixed frequency ratio, while maintaining a stress level in the suspension assembly sufficiently low. Additional shaping of the suspension beams may provide further stress reduction in the suspension assembly. The suspension assembly may include piezoelectric actuation structures (e.g., piezoelectric actuators) and piezoelectric sensors arranged on the plurality of suspension beams for actuation and sensing.

### BACKGROUND

A scanning system may use two-dimensional scanning to scan one or more light beams within a field-of-view (FOV) according to a scanning pattern. The scanning system may use two scanning axes, including a first scanning axis that is configured to steer the one or more light beams in a first direction at a first scanning frequency and a second scanning axis that is configured to steer the one or more light beams in a second direction at a second scanning frequency. The second scanning axis is typically perpendicular to the first scanning axis. Different scanning patterns can be obtained by using different fixed frequency ratios between the first scanning frequency and the second scanning frequency. Synchronizing the first scanning frequency and the second scanning frequency to maintain a fixed frequency ratio is important to maintain a particular scanning pattern during a scanning operation.

### SUMMARY

In some implementations, a microelectromechanical system (MEMS) device includes a mirror system including a connector ring and a mirror body coupled to the connector ring, wherein the mirror body, arranged inside the connector ring, is configured to rotate about a first rotation axis and to rotate about a second rotation axis that is perpendicular to the first rotation axis; a frame that is rotationally fixed, the frame comprising a frame recess over which the mirror system is suspended; and a suspension assembly mechanically coupled to and between the mirror system and the frame, the suspension assembly configured to suspend the mirror system over the frame recess, wherein the suspension assembly comprises: a first anchor assembly attached to the frame at a first frame attachment point arranged on the second rotation axis; a second anchor assembly attached to the frame at a second frame attachment point arranged on the second rotation axis, wherein the first frame attachment point and the second frame attachment point are arranged on opposite sides of the mirror body along the second rotation axis; a first torsion beam coupled to the connector ring at a first mirror attachment point arranged on the first rotation axis, wherein the first torsion beam extends from the first mirror attachment point away from the connector ring along the first rotation axis to a first suspension beam attachment point; a second torsion beam coupled to the connector ring at a second mirror attachment point arranged on the first rotation axis, wherein the second torsion beam extends from the second mirror attachment point away from the connector ring along the first rotation axis to a second suspension beam attachment point, and wherein the first mirror attachment point and the second mirror attachment point are arranged on opposite sides of the mirror body along the first rotation axis; a first pair of outer suspension beams connected to the first suspension beam attachment point, wherein the first pair of outer suspension beams extend from the first suspension beam attachment point and connect to the first anchor assembly and to the second anchor assembly, respectively; a second pair of outer suspension beams connected to the second suspension beam attachment point, wherein the second pair of outer suspension beams extend from the second suspension beam attachment point and connect to the first anchor assembly and to the second anchor assembly, respectively; a first inner suspension beam connected to the first anchor assembly and the connector ring; a second inner suspension beam connected to the second anchor assembly and the connector ring; a third inner suspension beam connected to the first anchor assembly and the connector ring; and a fourth inner suspension beam connected to the second anchor assembly and the connector ring.

In some implementations, a MEMS device includes a mirror system including a connector ring and a mirror body coupled to the connector ring, wherein the mirror body, arranged inside the connector ring, is configured to rotate about a first rotation axis and rotate about a second rotation axis that is perpendicular to the first rotation axis; a frame that is rotationally fixed, the frame comprising a frame recess over which the mirror system is suspended; and a suspension assembly mechanically coupled to and between the mirror system and the frame, the suspension assembly configured to suspend the mirror system over the frame recess, wherein the suspension assembly comprises: a first anchor assembly attached to the frame at a first frame attachment point arranged on the second rotation axis; a second anchor assembly attached to the frame at a second frame attachment point arranged on the second rotation axis, wherein the first frame attachment point and the second frame attachment point are arranged on opposite sides of the mirror body along the second rotation axis; a first inner torsion beam coupled to the connector ring at a first mirror attachment point arranged on the first rotation axis, wherein the first inner torsion beam extends from the first mirror attachment point away from the connector ring along the first rotation axis to a first inner suspension beam attachment point; a second inner torsion beam coupled to the connector ring at a second mirror attachment point arranged on the first rotation axis, wherein the second inner torsion beam extends from the second mirror attachment point away from the connector ring along the first rotation axis to a second inner suspension beam attachment point, and wherein the first mirror attachment point and the second mirror attachment point are arranged on opposite sides of the mirror body along the first rotation axis; a first outer torsion beam coupled to the first inner suspension beam attachment point, wherein the first outer torsion beam extends from the first inner suspension beam attachment point away from the connector ring along the first rotation axis to a first outer suspension beam attachment point; a second outer torsion beam coupled to the second inner suspension beam attachment point, wherein the second outer torsion beam extends from the second inner suspension beam attachment point away from the connector ring along the first rotation axis to a second outer suspension beam attachment point; a first pair of inner suspension beams connected to the first inner suspension beam attachment point, wherein the first pair of outer suspension beams extend from the first inner suspension beam attachment point and connect to the first anchor assembly and to the second anchor assembly, respectively; a second pair of inner suspension beams connected to the second inner suspension beam attachment point, wherein the second pair of outer suspension beams extend from the second inner suspension beam attachment point and connect to the first anchor assembly and to the second anchor assembly, respectively; a first pair of outer suspension beams connected to the first outer suspension beam attachment point, wherein the first pair of outer suspension beams extend from the first outer suspension beam attachment point and connect to the first anchor assembly and to the second anchor assembly, respectively; and a second pair of outer suspension beams connected to the second outer suspension beam attachment point, wherein the second pair of outer suspension beams extend from the second outer suspension beam attachment point and connect to the first anchor assembly and to the second anchor assembly, respectively.

### BRIEF DESCRIPTION OF THE DRAWINGS

Implementations are described herein making reference to the appended drawings.

FIG. 1 is a schematic block diagram of a 2D scanning system, according to one or more implementations.

FIG. 2A shows a top view of a MEMS device according to one or more implementations.

FIG. 2B shows a cross-section view of the MEMS device.

FIG. 2C shows an isometric view of the MEMS device.

FIG. 2D shows an isometric view of the MEMS device as the MEMS device rotates about the second rotation axis.

FIG. 2E shows an isometric view of the MEMS device as the MEMS device rotates about the first rotation axis.

FIGS. 3A-3E show MEMS devices with alternative design configurations.

FIG. 4 shows a top view of a MEMS device according to one or more implementations.

### DETAILED DESCRIPTION

In the following, details are set forth to provide a more thorough explanation of example implementations. However, it will be apparent to those skilled in the art that these implementations may be practiced without these specific details. In other instances, well-known structures and devices are shown in block diagram form or in a schematic view, rather than in detail, in order to avoid obscuring the implementations. In addition, features of the different implementations described hereinafter may be combined with each other, unless specifically noted otherwise.

Further, equivalent or like elements or elements with equivalent or like functionality are denoted in the following description with equivalent or like reference numerals. As the same or functionally equivalent elements are given the same reference numbers in the figures, a repeated description for elements provided with the same reference numbers may be omitted. Hence, descriptions provided for elements having the same or like reference numbers are mutually interchangeable.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “top,” “bottom,” “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

In implementations described herein or shown in the drawings, any direct electrical connection or coupling (e.g., any connection or coupling without additional intervening elements) may also be implemented by an indirect connection or coupling (e.g., a connection or coupling with one or more additional intervening elements, or vice versa) as long as the general purpose of the connection or coupling (e.g., to transmit a certain kind of signal or to transmit a certain kind of information) is essentially maintained. Features from different implementations may be combined to form further implementations. For example, variations or modifications described with respect to one of the implementations may also be applicable to other implementations unless noted to the contrary.

As used herein, the terms “substantially” and “approximately” mean “within reasonable tolerances of manufacturing and measurement.” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, a signal with an approximate signal value may practically have a signal value within 5% of the approximate signal value.

In the present disclosure, expressions including ordinal numbers, such as “first”, “second”, and/or the like, may modify various elements. However, such elements are not limited by such expressions. For example, such expressions do not limit the sequence and/or importance of the elements. Instead, such expressions are used merely for the purpose of distinguishing an element from the other elements. For example, a first box and a second box indicate different boxes, although both are boxes. For further example, a first element could be termed a second element, and similarly, a second element could also be termed a first element without departing from the scope of the present disclosure.

A microelectromechanical system (MEMS) mirror can be driven about two or more scanning axes for use as a scanning device. Alternatively, two MEMS mirrors driven about a respective scanning axis may be optically coupled to form a scanning system. A MEMS mirror-based light beam scanner is one way to implement image projection technologies and object detection technologies such as Light Detection and Ranging (LIDAR). These technologies may rely on a two-dimensional (2D) scanning pattern, such as a Lissajous scanning pattern, that relies on accurately synchronized scanning axes driven at scanning frequencies that have a fixed frequency ratio.

Resonant MEMS scanning micromirrors show great potential as a key component of future miniaturized projection systems. MEMS scanning micromirrors are microstructured resonators. Thus, MEMS scanning micromirrors feature structural members, such as springs, that function as spring system (e.g., a suspension system) and also feature a rigid mirror body, which is suspended by the suspension system. Together, the springs and the rigid mirror body form a spring-mass system that can be excited in one or several eigenmodes by a suitable actuation mechanism to induce a desired oscillatory motion of the rigid mirror body. Usually, in a MEMS, the actuation mechanism is either electrostatic (capacitive), piezoelectric, or electromagnetic. For micromirrors implemented in projection applications, desired eigenmodes are two perpendicular rotatory motions of the rigid mirror body. The rigid mirror body typically has a circular or elliptical surface with high reflectivity, which represents a reflective surface that may also be referred to as a mirror surface. Often, the entire MEMS structure is called a MEMS mirror. When one or two rotatory eigenmodes of the rigid mirror body are excited, in which the rotation axis or axes lie(s) in a plane of the reflective surface, a normal to the plane of the reflective surface will travel in an oscillatory motion in one or two directions. If a light beam of a collimated light source, such as a laser, is directed onto the reflective surface, an angle of incidence will change according to a motion of the normal. The motion of the normal will steer a reflected beam accordingly. If laser beam scanning is performed in two directions and in a controlled fashion, the reflected beam can be steered at a solid angle with knowledge of current angular coordinates with respect to the normal of the reflective surface at a resting position. If a red, green, and blue (RGB) light source, having three laser diodes forming RGB channels, is pulsed and turned on and off in a controlled fashion according to a current position of the MEMS mirror, a beam scanning system can form a projection apparatus that may project desired image content on a screen.

A performance of the beam scanning system may be defined by at least four key properties of the MEMS mirror, including the frequencies of two operational rotatory eigenmodes in which the MEMS mirror is excited, a diameter of the reflective surface of the mirror body, maximum angular amplitudes of the resonant oscillatory motions, to which the two rotatory eigenmodes are excited, and a dynamic deformation of the reflective surface of the mirror body.

The frequencies of the two operational rotatory eigenmodes determine the angular distance, which the trajectories of both scanning axes can travel in a given amount of time. The trajectory of one scanning axis in single operation may be defined by an angle of the reflective surface normal measured versus the normal at the rest position as a function of time. In simultaneous excitation of both axes, the trajectory is a 2D-angle of the reflective surface normal as a function of time measured versus the normal at the rest position. The more angular distance the reflective surface can travel in a given amount of time, the more image content can be projected in the same amount of time. For this reason, the frequencies can be understood to determine a resolution of a projection device.

The MEMS mirror is part of an optical system. For this reason, the mirror body needs a certain diameter in order to avoid unwanted optical effects, such as diffraction.

The maximum angular amplitudes define the solid angle, in which the trajectory of the reflective surface normal travels. Thus, the maximum angular amplitudes define the optical field-of-view of the projection, and thus a size of a projected image at a given distance from the projection device.

The mirror body is not perfectly rigid. Since the mirror body is repeatedly accelerated and decelerated in resonant motions, the mirror body will deform under its own inertia. This is called dynamic deformation. Dynamic deformation deteriorates an optical projection quality because the reflective surface will not be a perfect plane, but will instead have surface regions that are out-of-plane (e.g., curved or otherwise deformed from being straight).

A challenge in designing MEMS mirrors is therefore to make the mirror body as rigid as possible while reducing an inertia or mass of the mirror body in order to reduce the dynamic deformation and yield a better projection quality. At the same time, this process often also reduces the moments of inertia associated with the two rotatory eigenmodes. Reduction of inertia leads to higher frequencies, and thus higher resolution. Alternatively, the reduction in inertia can be leveraged to reduce mechanical stress in the suspension system. For example, a basic relation of frequency f, spring constant k, and inertia I associated with a certain mode can be expressed by the following equation 2πf=√(k/I). A reduction in inertia allows a reduction of the spring constant, when a constant frequency is desired. A reduction of the spring constant can usually be translated into a reduction of maximum mechanical stress appearing in the suspension system during the oscillation, which may improve the reliability of the MEMS mirror and/or will allow for higher maximum angular amplitudes.

Achieving large field-of-view and resolution with laser beam scanning technology using 2D MEMS scanning requires MEMS mirrors to have a very high resonance frequency (bi-resonant) and reach high mechanical angles (e.g., angles greater than 10°). The 2D MEMS mirror should also be driven with precise frequency ratio, or frequency difference, between two operational modes. The operational modes correspond to oscillations about two scanning axes (e.g., two rotation axes), respectively. Thus, the 2D MEMS mirror should also be driven such that oscillation frequencies of the 2D MEMS mirror about the two scanning axes are maintained at a precise frequency ratio.

Some implementations disclosed herein are directed to a suspension assembly for a MEMS mirror (e.g., a micro-mirror). For example, the MEMS mirror may be embedded in the suspension assembly. The suspension assembly includes a plurality of torsion beams and a plurality of suspension beams that are attached to a fixed frame and a mirror body of the MEMS mirror. Additionally, the suspension assembly may include piezoelectric actuation structures (e.g., piezoelectric actuators) and piezoelectric sensors arranged on the plurality of suspension beams for actuation and sensing. For example, the piezoelectric actuation structures may actuate deformations or deflections of the plurality of suspension beams to induce rotation of the MEMS mirror about two rotation axes. The MEMS mirror may be driven about each rotation axis at a respective frequency (e.g., a respective oscillation frequency or resonant frequency) such that a fixed frequency ratio between frequencies is achieved. The piezoelectric sensors may measure the deformations as feedback information to a controller.

In some implementations, the suspension assembly includes four pairs of suspension beams connecting the mirror body to the fixed frame. The four pairs of suspension beams may enable tuning of the oscillation frequencies (e.g., resonant frequencies) to a desired frequency ratio, while maintaining a stress level in the suspension assembly sufficiently low. Additional shaping of the suspension beams may provide further stress reduction in the suspension assembly.

In some implementations, a MEMS device includes a mirror body coupled to a stiffening structure, which is anchored to a connector ring by four connection structures, a suspension assembly (acting as spring elements), and a frame. The suspension assembly enables the mirror body to rotate around two rotation axes, including first rotation axis (e.g., a fast axis) and a second rotation axis (e.g., slow axis). The mirror body may rotate (e.g., oscillate) about the first rotation axis at a higher frequency (e.g., a faster frequency) than a frequency at which the mirror body rotates about the second rotation axis. For example, the suspension assembly may enable the mirror body to oscillate about the first rotation axis at a first frequency and to oscillate about the second rotation axis at a second frequency that is lower than the first frequency.

The suspension assembly may include several different parts serving different functions. For example, the suspension assembly may include a section connected to the mirror body, composed of torsion beams, is aligned with one axis of rotation (fast axis) to limit stress and designed to be stiff enough (in torsion). Additionally, the suspension assembly may include four pairs of suspension beams that connect the mirror body (via the aforementioned torsion beams) to the frame. The four pairs of suspension beams may include two pairs of suspension beams forming an inner part of the suspension assembly, and two pairs of suspension beams forming an outer part of the suspension assembly. The four pairs of suspension beams are wide enough to accommodate the piezoelectric actuation structures and piezoelectric sensors.

The four pairs of suspension beams may include different sections that can be designed to adjust the stress over respective lengths of the four pairs of suspension beams. Each section length and width may be adjusted independently. Possible configurations of inner beams may include three to four sections, with each section having a constant width; three to four sections, with a nonconstant width for each section; three to four sections control points such that each suspension beam is designed using splines following the control points. Each section of the suspension beam may be defined by two splines, with or without constant distance between the splines. The suspension beams may also be shaped with mix of any of the above design configurations.

The suspension beams may be anchored to the frame either straight (aligned to the second axis of rotation, slow axis) or with an angle (up to 10°) for better parasitic modes separation. At an anchor, a notch may be provided at a central area of the anchor in order to reduce the stress at this location for the rotation of suspension assembly around the second rotation axis.

In some implementations, two pairs of outer beams are connected to the mirror body, each pair via a single torsion beam, and inner beams are each connected to the mirror body via a dedicated torsion beam. In some implementations, two pairs of outer beams and two pairs of inner beams are provided. Each pair of the two pairs of inner beams may be respectively connected to the mirror body via a respective inner torsion beam centered on the first rotation axis, and each pair of the two pairs of outer beams may be respectively connected to a respective inner torsion beam by a respective outer torsion beam that is centered on the first rotation axis and is connected in series with the respective inner torsion beam. Different beam arrangements may be chosen based on a stiffness required, with beam arrangements with fewer torsion beams providing better parasitic modes separation

According to a side view or a cross-section view of the MEMS device, the mirror body may be formed by a first layer having a layer thickness between 5-25 μm, the suspension assembly may be formed by the first layer and a second layer, with a total thickness between 60-140 μm, and the stiffening structure may be formed by the second layer and a third layer, with a total thickness between 150-400 μm. The stiffening structure may have a relatively large thickness to ensure stability of the MEMS mirror with low dynamic deformation

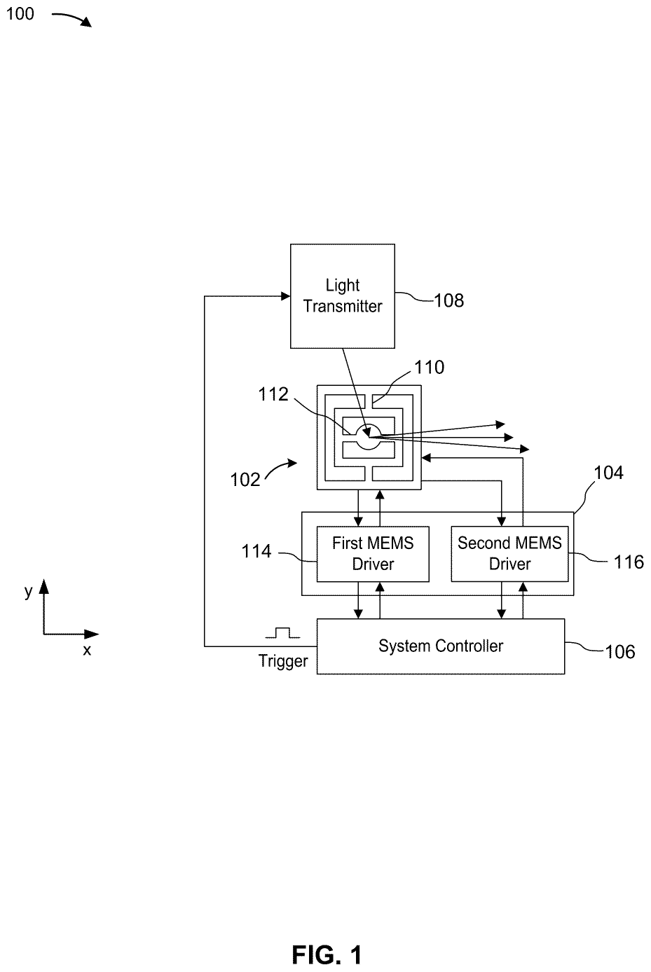

FIG. 1 is a schematic block diagram of a 2D scanning system 100, according to one or more implementations. In particular, the 2D scanning system 100 includes a microelectromechanical system (MEMS) mirror 102 implemented as a single scanning structure that is configured to steer or otherwise deflect light beams according to a 2D scanning pattern. The 2D scanning system 100 further includes a MEMS driver system 104, a system controller 106, and a light transmitter 108.

In the example shown in FIG. 1, the MEMS mirror 102 is a mechanical moving mirror (e.g., a MEMS micro-mirror) integrated on a semiconductor chip (not shown). The MEMS mirror 102 is configured to rotate or oscillate via rotation about two scanning axes (e.g., two rotation axes) that are typically orthogonal to each other. For example, the two scanning axes may include a first scanning axis 110 (e.g., an outer scanning axis) that enables the MEMS mirror 102 to steer light in a first scanning direction (e.g., an x-direction) and a second scanning axis 112 (e.g., an inner scanning axis) that enables the MEMS mirror 102 to steer light in a second scanning direction (e.g., a y-direction). As a result, the MEMS mirror 102 can direct light beams in two dimensions according to the 2D scanning pattern and may be referred to as a 2D MEMS mirror.

The MEMS mirror 102 may include a mirror body (e.g., a mirror plate) that has a reflective surface for reflecting light. For example, a reflective layer may be arranged on an upper surface of the mirror body to form the reflective surface. The mirror body may be attached to a suspension assembly by, for example, suspension structures, such as one or more pairs suspension beams. A pair of suspension beams may extend along a respective scanning axis for attaching the mirror plate to a rotationally fixed frame. The suspension beams of a pair of suspension beams may be arranged on opposite sides of the mirror body. The suspension system suspends the mirror body over a cavity to provide the mirror body with sufficient clearance to rotate about the two scanning axes. Thus, the suspension assembly enables rotation of the mirror body about the two scanning axes.

A scan can be performed to illuminate an area referred to as a field-of-view. The scan, such as an oscillating horizontal scan (e.g., from left to right and right to left of a field-of-view), an oscillating vertical scan (e.g., from bottom to top and top to bottom of a field-of-view), or a combination thereof (e.g., a Lissajous scan or a raster scan) can illuminate the field-of-view in a continuous scan fashion. In some implementations, the 2D scanning system 100 may be configured to transmit successive light beams (e.g., as successive light pulses) in different scanning directions to scan the field-of-view. In some implementations, the 2D scanning system 100 may be configured to transmit a continuous light beam (e.g., as a frequency-modulated continuous-wave (FMCW)) in different scanning directions to scan the field-of-view. In other words, the field-of-view can be illuminated by a scanning operation. In general, an entire field-of-view represents a scanning area defined by a full range of motion of the MEMS mirror 102 at which the MEMS mirror 102 is driven. Thus, the entire field-of-view is delineated by a left edge, a right edge, a bottom edge, and a top edge. The entire field-of-view can also be referred to as a field of illumination or as a projection area in a projection plane onto which an image is projected.

The MEMS mirror 102 can direct a transmitted light beam at a desired 2D coordinate (e.g., an x-y coordinate) in the field-of-view. In some implementations, such as Light Detection and Ranging (LIDAR), the MEMS mirror 102 may be arranged to receive transmitted light beams from the light transmitter 108 and steer (scan) the transmitted light beams into the field-of-view to perform a scanning of the environment. The transmitted light beams may be backscattered by one or more objects back toward the 2D scanning system 100 as reflected light beams, where the reflected light beams are detected by a sensor. For example, the sensor may be a photodetector array. The sensor may convert each reflected light beam into an electric signal (e.g., a current signal or a voltage signal) that may be further processed by the 2D scanning system 100 to generate object data or an image. In such implementations, the desired 2D coordinate may correspond to a particular transmission direction in the field-of-view that is targeted by the transmitted light beam for object detection, with different 2D coordinates corresponding to different transmission directions.

Alternatively, in some implementations, such as image projection systems, the desired 2D coordinate may correspond to an image pixel of a projected image, with different 2D coordinates corresponding to different image pixels of the projected image. In some implementations, an image projection system may include wearable augmented reality goggles and the MEMS mirror 102 may be arranged to receive the transmitted light beams and steer (scan) the transmitted light beams onto a retina of a human eye in order to render an image thereon. In some implementations, an image projection system may include a head-up display (HUD) and the MEMS mirror 102 may be arranged to receive the transmitted light beams and steer (scan) the transmitted light beams onto a display screen.

Accordingly, multiple light beams transmitted at different transmission times or a continuous light beam can be steered by the MEMS mirror 102 at the different 2D coordinates of the field-of-view in accordance with the 2D scanning pattern. The MEMS mirror 102 can be used to scan the field-of-view in both scanning directions by changing an angle of deflection of the MEMS mirror 102 on each of the first scanning axis 110 and the second scanning axis 112.

A rotation of the MEMS mirror 102 on the first scanning axis 110 may be performed between two predetermined extremum deflection angles (e.g., +/−5 degrees, +/−15 degrees, etc.). Likewise, a rotation of the MEMS mirror 102 on the second scanning axis 112 may be performed between two predetermined extremum deflection angles (e.g., +/−5 degrees, +/−15 degrees, etc.). In some implementations, depending on the 2D scanning pattern, the two predetermined extremum deflection angles used for the first scanning axis 110 may be the same as the two predetermined extremum deflection angles used for the second scanning axis 112. In some implementations, depending on the 2D scanning pattern, the two predetermined extremum deflection angles used for the first scanning axis 110 may be different from the two predetermined extremum deflection angles used for the second scanning axis 112.

In some implementations, the MEMS mirror 102 can be a resonator (e.g., a resonant MEMS mirror) configured to oscillate side-to-side about the first scanning axis 110 at a first frequency (e.g., a first resonance frequency) and configured to oscillate top-to-bottom about the second scanning axis 112 at a second frequency (e.g., a second resonance frequency). Thus, the MEMS mirror 102 can be continuously driven about the first scanning axis 110 and the second scanning axis 112 to perform a continuous scanning operation. As a result, light beams reflected by the MEMS mirror 102 are scanned into the field-of-view in accordance with the 2D scanning pattern.

Different frequencies or a same frequency may be used for the first scanning axis 110 and the second scanning axis 112 for defining the 2D scanning pattern. For example, a raster scanning pattern or a Lissajous scanning pattern may be achieved by using different frequencies for the first frequency and the second frequency. Raster scanning and Lissajous scanning are two types of scanning that can be implemented in display applications, light scanning applications, and light steering applications, to name a few. As an example, Lissajous scanning is typically performed using two resonant scanning axes which are driven at different constant scanning frequencies with a defined fixed frequency ratio therebetween that forms a specific Lissajous pattern and frame rate. In order to properly carry out the Lissajous scanning or the raster scanning, synchronization of the two scanning axes is performed by the system controller 106 in conjunction with transmission timings of the light transmitter 108.

For each respective scanning axis, including the first scanning axis 110 and the second scanning axis 112, the MEMS mirror 102 includes an actuator structure used to drive the MEMS mirror 102 about the respective scanning axis. Each actuator structure may include interdigitated finger electrodes made of interdigitated mirror combs and frame combs to which a drive voltage (e.g., an actuation signal or driving signal) is applied by the MEMS driver system 104. Applying a difference in electrical potential between interleaved mirror combs and frame combs creates a driving force between the mirror combs and the frame combs, which creates a torque on the mirror body of the MEMS mirror 102 about the intended scanning axis. The drive voltage can be toggled between two voltages, resulting in an oscillating driving force. The oscillating driving force causes the MEMS mirror 102 to oscillate back and forth on the respective scanning axis between two extrema. Depending on the configuration, this actuation can be regulated or adjusted by adjusting a drive voltage off time, a voltage level of the drive voltage (e.g., a high-voltage (HV) level), or a duty cycle.

In other examples, the MEMS mirror 102 may use other actuation methods to drive the MEMS mirror 102 about the respective scanning axes. For example, these other actuation methods may include electromagnetic actuation and/or piezoelectric actuators. In electromagnetic actuation, the MEMS mirror 102 may be immersed in a magnetic field and an alternating electric current through conductive paths may create the oscillating torque around the scanning axis. Piezoelectric actuators may be integrated in leaf springs of the MEMS mirror 102, or the leaf springs may be made of piezoelectric material to produce alternating beam bending forces in response to an electrical signal to generate the oscillation torque.

The MEMS driver system 104 may be configured to generate driving signals (e.g., actuation signals) to drive the MEMS mirror 102 about the first scanning axis 110 and the second scanning axis 112. In particular, the MEMS driver system 104 may be configured to apply the driving signals to the actuator structure of the MEMS mirror 102. In some implementations, the MEMS driver system 104 includes a first MEMS driver 114 configured to drive the MEMS mirror 102 about the first scanning axis 110 and a second MEMS driver 116 configured to drive the MEMS mirror 102 about the second scanning axis 112. In implementations in which the MEMS mirror 102 is used as an oscillator, the first MEMS driver 114 is configured to drive an oscillation of the MEMS mirror 102 about the first scanning axis 110 at the first frequency, and the second MEMS driver 116 is configured to drive an oscillation of the MEMS mirror 102 about the second scanning axis 112 at the second frequency.

The first MEMS driver 114 may be configured to sense an outer axis movement (e.g., a first rotational position) of the MEMS mirror 102 about the first scanning axis 110 using an outer axis sensor and provide first position information indicative of the first rotational position (e.g., tilt angle or degree of rotation about the first scanning axis 110) to the system controller 106. Similarly, the second MEMS driver 116 may be configured to sense an inner axis movement (e.g., a second rotational position) of the MEMS mirror 102 about the second scanning axis 112 using an inner axis sensor and provide second position information indicative of the second rotational position (e.g., tilt angle or degree of rotation about the second scanning axis 112) to the system controller 106.

The system controller 106 may use the first position information and the second position information to trigger light beams at the light transmitter 108. For example, the system controller 106 may use the first position information and the second position information to set a transmission time of light transmitter 108 in order to target a particular 2D coordinate of the 2D scanning pattern. Thus, a higher accuracy in position sensing of the MEMS mirror 102 by the first MEMS driver 114 and the second MEMS driver 116 may result in the system controller 106 providing more accurate and precise control of other components of the 2D scanning system 100.

As noted above, the first MEMS driver 114 and the second MEMS driver 116 may apply a drive voltage to a corresponding actuator structure of the MEMS mirror 102 as the driving signal to drive a rotation (e.g., an oscillation) of the MEMS mirror 102 about a respective scanning axis (e.g., the first scanning axis 110 or the second scanning axis 112). The drive voltage can be switched or toggled between an HV level and a low-voltage (LV) level resulting in an oscillating driving force. In some implementations, the LV level may be zero (e.g., the drive voltage is off), but is not limited thereto and could be a non-zero value. When the drive voltage is toggled between an HV level and an LV level, and the LV level is set to zero, it can be said that the drive voltage is toggled on and off (HV on/off). The oscillating driving force causes the MEMS mirror 102 to oscillate back and forth on the first scanning axis 110 or the second scanning axis 112 between two extrema. The drive voltage may be a constant drive voltage, meaning that the drive voltage is the same voltage when actuated (e.g., toggled on), or one or both of the HV level or the LV level of the drive voltage may be adjustable. However, it will be understood that the drive voltage is being toggled between the HV level and the LV level in order to produce the mirror oscillation. Depending on a configuration, this actuation can be regulated or adjusted by the system controller 106 by adjusting the drive voltage off time, a voltage level of the drive voltage, or a duty cycle. As noted above, frequency and phase of the drive voltage can also be regulated and adjusted.

In some implementations, the system controller 106 is configured to set a driving frequency of the MEMS mirror 102 for each scanning axis and is capable of synchronizing the oscillations about the first scanning axis 110 and the second scanning axis 112. In particular, the system controller 106 may be configured to control an actuation of the MEMS mirror 102 about each scanning axis by controlling the driving signals. The system controller 106 may control the frequency, the phase, the duty cycle, the HV level, and/or the LV level of the driving signals to control the actuations about the first scanning axis 110 and the second scanning axis 112. The actuation of the MEMS mirror 102 about a particular scanning axis controls its range of motion and scanning rate about that particular scanning axis.

For example, to make a Lissajous scanning pattern reproduce itself periodically with a frame rate frequency, the first frequency at which the MEMS mirror 102 is driven about the first scanning axis 110 and the second frequency at which the MEMS mirror 102 is driven about the second scanning axis 112 are different. A difference between the first frequency and the second frequency is set by a fixed frequency ratio that is used by the 2D scanning system 100 to form a repeatable Lissajous pattern (frame) with a frame rate. A new frame begins each time the Lissajous scanning pattern restarts, which may occur when a phase difference between a mirror phase about the first scanning axis 110 and a mirror phase about the second scanning axis 112 is zero. The system controller 106 may set the fixed frequency ratio and synchronize the oscillations about the first scanning axis 110 and the second scanning axis 112 to ensure that this fixed frequency ratio is maintained based on the first position information and the second position information received from the first MEMS driver 114 and the second MEMS driver 116, respectively.

The light transmitter may include one or more light sources, such as one or more laser diodes or one or more light emitting diodes, for generating one or more light beams. In some implementations, the light transmitter 108 may be configured to sequentially transmit a plurality of light beams (e.g., light pulses) as the MEMS mirror 102 changes its transmission direction in order to target different 2D coordinates. The plurality of light beams may include visible light, infrared (IR) light, or other types of illumination signals, depending on an application of the 2D scanning system 100. A transmission sequence of the plurality of light beams and a timing thereof may be implemented by the light transmitter 108 according to a trigger signal received from the system controller 106. Alternatively, in some implementations, the light transmitter 108 may be configured to transmit a continuous light beam as the MEMS mirror 102 changes its transmission direction in order to target different 2D coordinates. The continuous light beam may include visible light, IR light, or another type of illumination signal, depending on the application of the 2D scanning system 100.

The system controller 106 is configured to control components of the 2D scanning system 100. In certain applications, the system controller 106 may also be configured to receive programming information with respect to the 2D scanning pattern and control a timing of the plurality of light beams generated by the light transmitter 108 based on the programming information. Thus, the system controller 106 may include both processing and control circuity that is configured to generate control signals for controlling the light transmitter 108, the first MEMS driver 114, and the second MEMS driver 116.

In some implementations, the system controller 106 is configured to use independent measurements of the outer axis movement about the first scanning axis 110 and the inner axis movement about the second scanning axis 112 to drive and correctly synchronize transmission timings of the plurality of light beams with the movements of the MEMS mirror 102 and to synchronize a first scanning frequency of the first scanning axis 110 and a second scanning frequency of the second scanning axis 112. For example, the system controller 106 may be configured to set the driving frequencies of the MEMS mirror 102 for the first scanning axis 110 and the second scanning axis 112, and may be capable of synchronizing the oscillations about the first scanning axis 110 and the second scanning axis 112 to generate the 2D scanning pattern. In some implementations, in which the plurality of light beams is used, the system controller 106 may be configured to generate the trigger signal used for triggering the light transmitter 108 to generate the plurality of light beams. Using the trigger signal, the system controller 106 can control the transmission times of the plurality of light beams of the light transmitter 108 to achieve a desired illumination pattern within the field-of-view. The desired illumination pattern is produced by a combination of the 2D scanning pattern produced by the MEMS mirror 102 and the transmission times triggered by the system controller 106. In some implementations in which the continuous light beam is used, the system controller 106 may be configured to control a frequency modulation of the continuous light beam via a control signal provided to the light transmitter 108.

As indicated above, FIG. 1 is provided as an example. Other examples may differ from what is described with regard to FIG. 1. In practice, the 2D scanning system 100 may include additional components, fewer components, different components, or differently arranged components than those shown in FIG. 1 without deviating from the disclosure provided above. In addition, in some implementations, the 2D scanning system 100 may include one or more additional 2D MEMS mirrors or one or more additional light transmitters used to scan one or more additional field-of-views. Additionally, two or more components shown in FIG. 1 may be implemented within a single component, or a single component shown in FIG. 1 may be implemented as multiple, distributed components. Additionally, or alternatively, a set of components (e.g., one or more components) of the 2D scanning system 100 may perform one or more functions described as being performed by another set of components of the 2D scanning system 100.

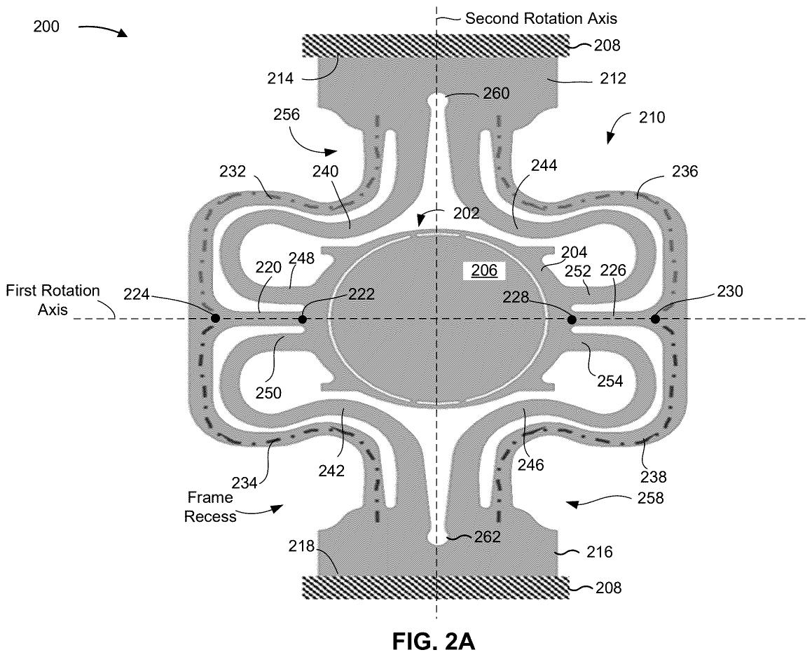

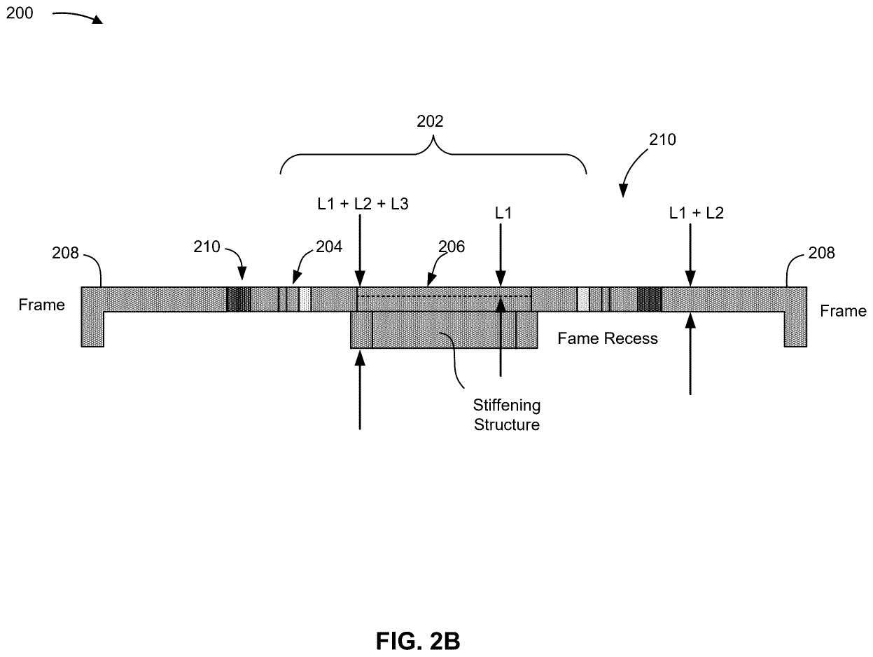

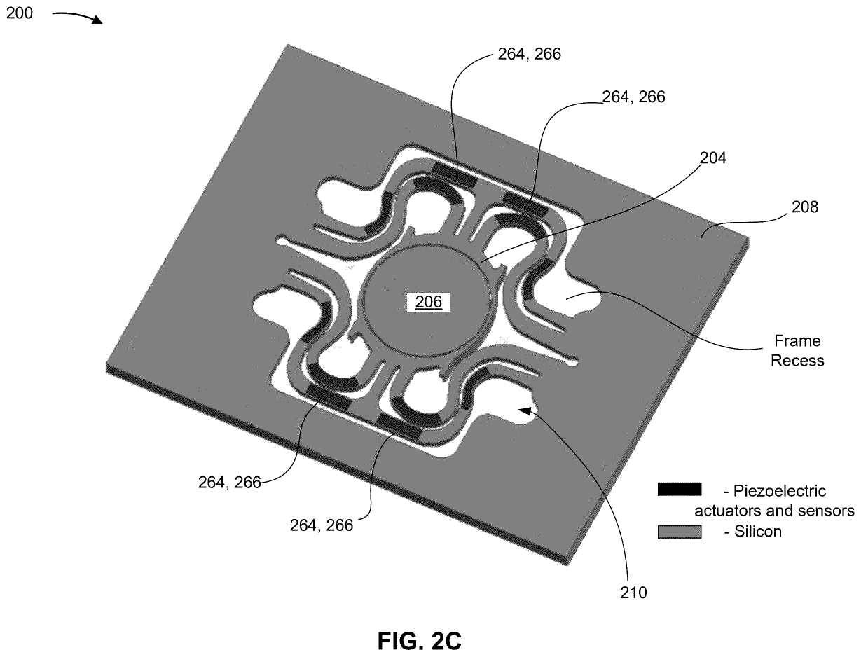

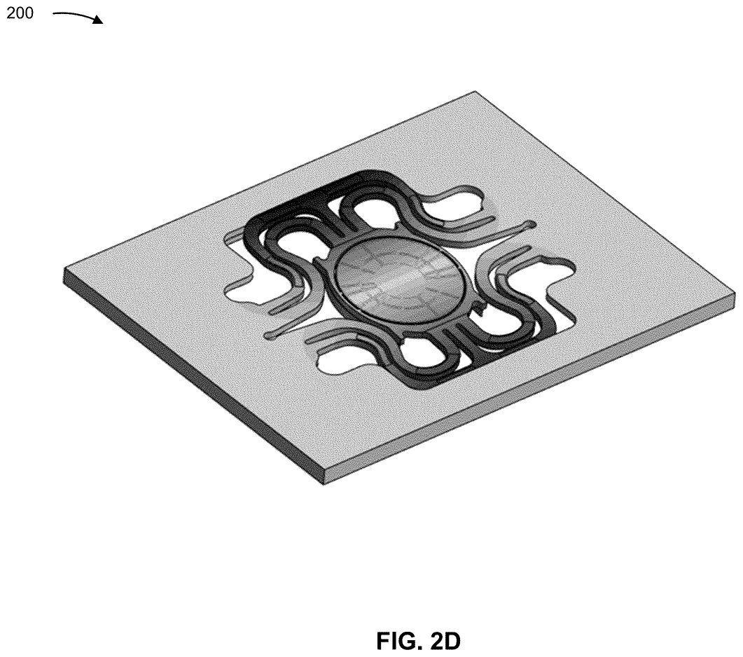

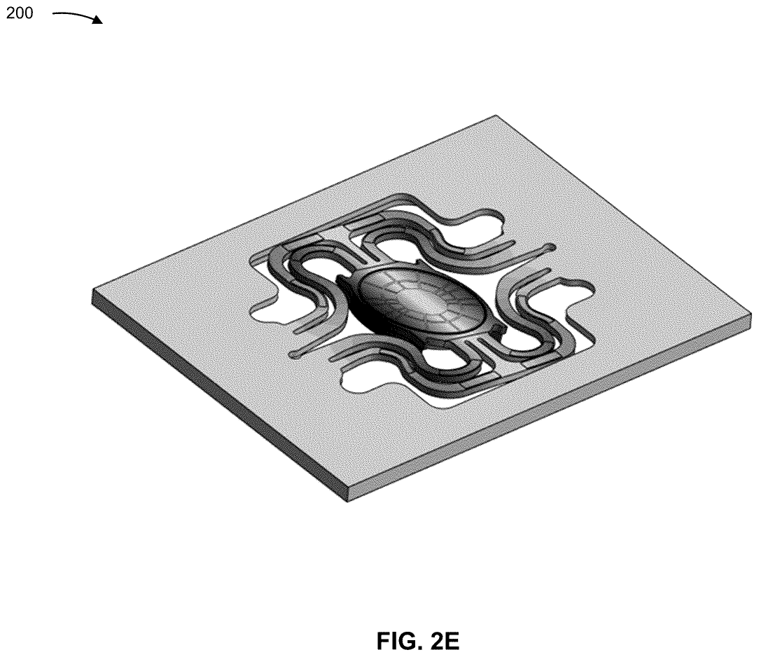

FIG. 2A shows a top view of a MEMS device 200 according to one or more implementations. The MEMS device 200 may be a MEMS mirror device. The MEMS device 200 may include a mirror system 202 including a connector ring 204 and a mirror body 206 coupled to the connector ring 204. The mirror body 206, arranged inside the connector ring 204, is configured to rotate about a first rotation axis (e.g., a fast axis) and to rotate about a second rotation axis (e.g., a slow axis) that is perpendicular to the first rotation axis. A frame 208 is provided that is rotationally fixed. The frame 208 may include or otherwise define a frame recess over which the mirror system 202 is suspended.

The MEMS device 200 may further include a suspension assembly 210 mechanically coupled to and between the mirror system 202 and the frame 208, the suspension assembly 210 configured to suspend the mirror system 202 over the frame recess. The suspension assembly 210 may include a first anchor assembly 212 attached to the frame 208 at a first frame attachment point 214 arranged on the second rotation axis. Additionally, the suspension assembly 210 may include a second anchor assembly 216 attached to the frame 208 at a second frame attachment point 218 arranged on the second rotation axis, wherein the first frame attachment point 214 and the second frame attachment point 218 are arranged on opposite sides of the mirror body 206 along the second rotation axis. Additionally, the suspension assembly 210 may include a first torsion beam 220 coupled to the connector ring 204 at a first mirror attachment point 222 arranged on the first axis, wherein the first torsion beam extends from the first mirror attachment point 222 away from the connector ring 204 along the first rotation axis to a first suspension beam attachment point 224. Additionally, the suspension assembly 210 may include a second torsion beam 226 coupled to the connector ring 204 at a second mirror attachment point 228 arranged on the first axis, wherein the second torsion beam 226 extends from the second mirror attachment point 228 away from the connector ring 204 along the first rotation axis to a second suspension beam attachment point 230, and wherein the first mirror attachment point 222 and the second mirror attachment point 228 are arranged on opposite sides of the mirror body 206 along the first rotation axis.

Additionally, the suspension assembly 210 may include a first pair of outer suspension beams connected to the first suspension beam attachment point, wherein the first pair of outer suspension beams extend from the first suspension beam attachment point 224 and connect to the first anchor assembly 212 and to the second anchor assembly 216, respectively. The first pair of outer suspension beams may include a first outer suspension beam 232 that is attached to the first suspension beam attachment point 224 and to the first anchor assembly 212, and a second outer suspension beam 234 that is attached to the first suspension beam attachment point 224 and to the second anchor assembly 216.

Additionally, the suspension assembly 210 may include a second pair of outer suspension beams connected to the second suspension beam attachment point 230, wherein the second pair of outer suspension beams extend from the second suspension beam attachment point 230 and connect to the first anchor assembly 212 and to the second anchor assembly 216, respectively. The second pair of outer suspension beams may include a third outer suspension beam 236 that is attached to the second suspension beam attachment point 230 and to the first anchor assembly 212, and a fourth outer suspension beam 238 that is attached to the second suspension beam attachment point 230 and to the second anchor assembly 216

Additionally, the suspension assembly 210 may include a first inner suspension beam 240 connected to the first anchor assembly 212 and the connector ring 204, a second inner suspension beam 242 connected to the second anchor assembly 216 and the connector ring 204, a third inner suspension beam 244 connected to the first anchor assembly 212 and the connector ring 204, and a fourth inner suspension beam 246 connected to the second anchor assembly 216 and the connector ring 204.

The first inner suspension beam 240 may be arranged between the first outer suspension beam 232 and the mirror system 202. The second inner suspension beam 242 may be arranged between the second outer suspension beam 234 and the mirror system 202. The third inner suspension beam 244 may be arranged between the third outer suspension beam 236 and the mirror system 202. The fourth inner suspension beam 246 may be arranged between the fourth outer suspension beam 238 and the mirror system 202.

The first torsion beam, 220 the first inner suspension beam 240, and the second inner suspension beam 242 are attached to the connector ring 204 on a first lateral side of the connector ring 204. The second torsion beam 226, the third inner suspension beam 244, and the fourth inner suspension beam 246 are attached to the connector ring 204 on a second lateral side of the connector ring 204 opposite to the first lateral side.

The first inner suspension beam 240 may include a first torsion bar section 248 that extends parallel to the first torsion beam 220 and is attached to the connector ring 204. The second inner suspension beam 242 may include a second torsion bar section 250 that extends parallel to the first torsion beam 220 and is attached to the connector ring 204. The third inner suspension beam 244 may include a third torsion bar section 252 that extends parallel to the second torsion beam 226 and is attached to the connector ring 204 The fourth inner suspension beam 246 may include a fourth torsion bar section 254 that extends parallel to the second torsion beam 226 and is attached to the connector ring 204.

In some implementations, the first outer suspension beam 232, the third outer suspension beam 236, the first inner suspension beam 240, and the third inner suspension beam 244 may have parallel end sections that are attached to the first anchor assembly 212, with the parallel end sections being parallel to the second rotation axis. The second outer suspension beam 234, the fourth outer suspension beam 238, the second inner suspension beam 242, and the fourth inner suspension beam 246 have parallel end sections that are attached to the second anchor assembly 216, with the parallel end sections being parallel to the second rotation axis.

In some implementations, the first outer suspension beam 232, the third outer suspension beam 236, the first inner suspension beam 240, and the third inner suspension beam 244 may have end sections that are attached to the first anchor assembly 212 at an angle of 0° to 10° relative to the second rotation axis. In some examples, the first inner suspension beam 240 and the third inner suspension beam 244 are connected together at the first anchor assembly 212 in a V-shape. The second outer suspension beam 234, the fourth outer suspension beam 238, the second inner suspension beam 242, and the fourth inner suspension beam 246 may have end sections that are attached to the second anchor assembly 216 at an angle of 0° to 10° relative to the second rotation axis. In some examples, the second inner suspension beam 242 and the fourth inner suspension beam 246 are connected together at the second anchor assembly 216 in a V-shape.

In some implementations, the first outer suspension beam 232, the third outer suspension beam 236, the first inner suspension beam 240, and the third inner suspension beam 244 may have first end sections 256 that are attached to the first anchor assembly 212 The second outer suspension beam 234, the fourth outer suspension beam 238, the second inner suspension beam 242, and the fourth inner suspension beam 246 may have second end sections 258 that are attached to the second anchor assembly 216. The first anchor assembly 212 may include a first notch 260 that extends along the second rotation axis between the first end sections 256 of the first inner suspension beam 240 and the third inner suspension beam 244. The second anchor assembly 216 may include a second notch 262 that extends along the second rotation axis between the second end sections 258 of the second inner suspension beam 242 and the fourth inner suspension beam 246. The first notch 260 and the second notch 262 may be configured to reduce stress for rotation of the suspension assembly 210 about the second rotation axis.

As described above, the mirror body 206 may oscillate about the first rotation axis at a first frequency and to oscillate about the second rotation axis at a second frequency that is lower than the first frequency. Each suspension beam of the first pair of outer suspension beams (e.g., outer suspension beams 232 and 234), the second pair of outer suspension beams (e.g., outer suspension beams 236 and 238), the first inner suspension beam 240, the second inner suspension beam 242, the third inner suspension beam 244, and the fourth inner suspension beam 246 may be is respectively shaped to tune the first frequency, the second frequency, a maximum tilt amplitude about the first rotation axis, and a maximum tilt amplitude about the second rotation axis. For example, the suspension beams may be designed in a plurality of sections that have respective lengths, constant widths, non-constant widths, curved sections, straight sections, control points, splines, etc. In some implementations, each suspension beam of the first inner suspension beam 240, the second inner suspension beam 242, the third inner suspension beam 244, and the fourth inner suspension beam 246 may have three or more curved sections. Additionally, a shape of each suspension beam of the first inner suspension beam 240, the second inner suspension beam 242, the third inner suspension beam 244, and the fourth inner suspension beam 246 may be defined by two splines.

In some implementations, the first outer suspension beam 232, the second outer suspension beam 234, the first inner suspension beam 240, the second inner suspension beam 242 may be configured to be displaced, in-phase, about the second rotation axis. Additionally, the third outer suspension beam 236, the fourth outer suspension beam 238, the third inner suspension beam 244, the fourth inner suspension beam 246 may be configured to be displaced, in-phase, about the second rotation axis, and out-of-phase about the second rotation axis relative to the first outer suspension beam 232, the second outer suspension beam 234, the first inner suspension beam 240, the second inner suspension beam 242. Thus, the mode with out-of-phase rotation of inner beams with respect to outer beams around second rotation axis can be exploited (e.g., main mode targeted: in-phase rotation of inner beams with respect to outer beams around second rotation axis). Additionally, the first outer suspension beam 232, the third outer suspension beam 236, the first inner suspension beam 240, the third inner suspension beam 244 may be configured to be displaced, in-phase, about the first rotation axis. Additionally, the second outer suspension beam 234, the fourth outer suspension beam 238, the second inner suspension beam 242, the fourth inner suspension beam 246 may be configured to be displaced, in-phase, about the first rotation axis, and out-of-phase about the first rotation axis relative to the first outer suspension beam 232, the third outer suspension beam 236, the first inner suspension beam 240, the third inner suspension beam 244. Thus, the mode with out-of-phase rotation of inner beams with respect to outer beams around first rotation axis can be exploited (e.g., main mode targeted: in-phase rotation of inner beams with respect to outer beams around first rotation axis).

As indicated above, FIG. 2A is provided as an example. Other examples may differ from what is described with regard to FIG. 2A.

FIG. 2B shows a cross-section view of the MEMS device 200. The MEMS device 200 may be formed by a plurality of layers, including a first layer L1, a second layer L2, and a third layer L3. The plurality of layers may be semiconductor layers, such as silicon layers. A stiffening structure may be arranged underneath the mirror body 206 and is configured to support the mirror body 206. The stiffening structure may add rigidity to the mirror body 206 and reduce dynamic deformation of a reflective surface formed on the mirror body 206. The frame 208 may define a frame recess over which the mirror system 202 is suspended by the suspension assembly 210. The mirror body 206 may be formed by the first layer L1 having a layer thickness between 5-25 μm, the suspension assembly 210 may be formed by the first layer L1 and the second layer L2, with a total thickness between 60-140 μm, and the stiffening structure may be formed by the second layer L2 and the third layer L3, with a total thickness between 150-400 μm. The stiffening structure may have a relatively large thickness to ensure stability of the MEMS mirror with low dynamic deformation.

As indicated above, FIG. 2B is provided as an example. Other examples may differ from what is described with regard to FIG. 2B.

FIG. 2C shows an isometric view of the MEMS device 200. The MEMS device 200 may include a plurality of piezoelectric actuators 264 coupled to suspension beams of the suspension assembly 210. For example, at least one piezoelectric actuator 264 may be arranged on each suspension beam of the first pair of outer suspension beams (e.g., outer suspension beams 232 and 234), the second pair of outer suspension beams (e.g., outer suspension beams 236 and 238), the first inner suspension beam 240, the second inner suspension beam 242, the third inner suspension beam 244, and the fourth inner suspension beam 246. In some implementations, the inner suspension beams may include one piezoelectric actuator 264, and the outer suspension beams may include two piezoelectric actuators 264. The plurality of piezoelectric actuators 264 may be configured to induce deformations of the suspension beams to cause the mirror body 206 to rotate about the first rotation axis and the second rotation axis (e.g., for actuating rotations of the mirror body 206 about the first rotation axis and the second rotation axis). In other words, each piezoelectric actuator 264 may be coupled to a respective suspension beam to induce a deformation of the respective suspension beam. Piezoelectric structures (e.g., actuators and structures) are marked with dark patches.

An actuation circuit may be configured to generate actuation signals, and provide the actuation signals to the plurality of piezoelectric actuators 264 to control the deformations of the suspension beams. For example, the actuation circuit may be provided in a MEMS driver system, such as MEMS driver system 104. The first MEMS driver 114 and the second MEMS driver 116 may be configured to generate the actuation signals for actuating the piezoelectric actuators 264 and inducing controlled deformations of the suspension beam. In some implementations, a system controller, such as system controller 106 may generate the actuation signals for actuating the piezoelectric actuators 264. Thus, the actuation circuit is electrically coupled to the piezoelectric actuators 264. The actuation circuit may generate the actuation signals to maintain the in-phase and out-of-phase relationships of the suspension beams described above.

The MEMS device 200 may further include a plurality of piezoelectric sensors 266 coupled to the suspension beams. The plurality of piezoelectric sensors 266 may sense the deformations of the suspension beams and generate corresponding sensor signals. For example, the plurality of piezoelectric sensors 266 may generate electrical signals that are proportional to a sensed deformation. At least one piezoelectric sensor 266 may be arranged on each suspension beam. In some implementations, the inner suspension beams may include one piezoelectric sensor 266, and the outer suspension beams may include two piezoelectric sensors 266. The plurality of piezoelectric sensors 266 may provide the sensor signals to the actuation circuit as feedback information (e.g., deformation information, which may correspond to a rotational position or frequency of the mirror body 206). The actuation circuit may adjust an actuation of the plurality of piezoelectric actuators 264 based on the corresponding sensor signals to regulate movements of the mirror body 206 about the first rotation axis and the second rotation axis. For example, the actuation circuit may adjust an actuation of the plurality of piezoelectric actuators 264 in order to maintain a maximum tilt amplitude of the mirror body 206 about each rotation axis and/or to maintain a fixed frequency ratio between oscillation frequencies.

As indicated above, FIG. 2C is provided as an example. Other examples may differ from what is described with regard to FIG. 2C.

FIG. 2D shows an isometric view of the MEMS device 200 as the MEMS device 200 rotates about the second rotation axis. The first outer suspension beam 232, the second outer suspension beam 234, the first inner suspension beam 240, the second inner suspension beam 242 may be configured to be displaced, in-phase, about the second rotation axis. Additionally, the third outer suspension beam 236, the fourth outer suspension beam 238, the third inner suspension beam 244, the fourth inner suspension beam 246 may be configured to be displaced, in-phase, about the second rotation axis, and out-of-phase about the second rotation axis relative to the first outer suspension beam 232, the second outer suspension beam 234, the first inner suspension beam 240, the second inner suspension beam 242.

As indicated above, FIG. 2D is provided as an example. Other examples may differ from what is described with regard to FIG. 2D.

FIG. 2E shows an isometric view of the MEMS device 200 as the MEMS device 200 rotates about the first rotation axis. The first outer suspension beam 232, the third outer suspension beam 236, the first inner suspension beam 240, the third inner suspension beam 244 may be configured to be displaced, in-phase, about the first rotation axis. Additionally, the second outer suspension beam 234, the fourth outer suspension beam 238, the second inner suspension beam 242, the fourth inner suspension beam 246 may be configured to be displaced, in-phase, about the first rotation axis, and out-of-phase about the first rotation axis relative to the first outer suspension beam 232, the third outer suspension beam 236, the first inner suspension beam 240, the third inner suspension beam 244.

As indicated above, FIG. 2E is provided as an example. Other examples may differ from what is described with regard to FIG. 2E.

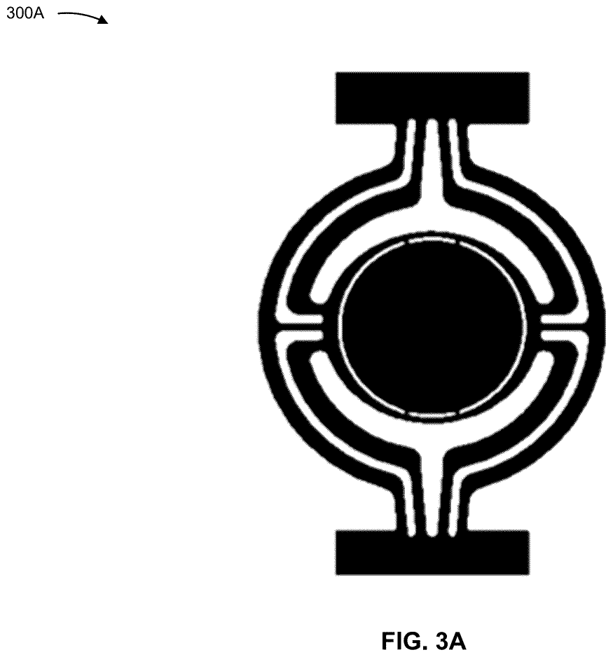

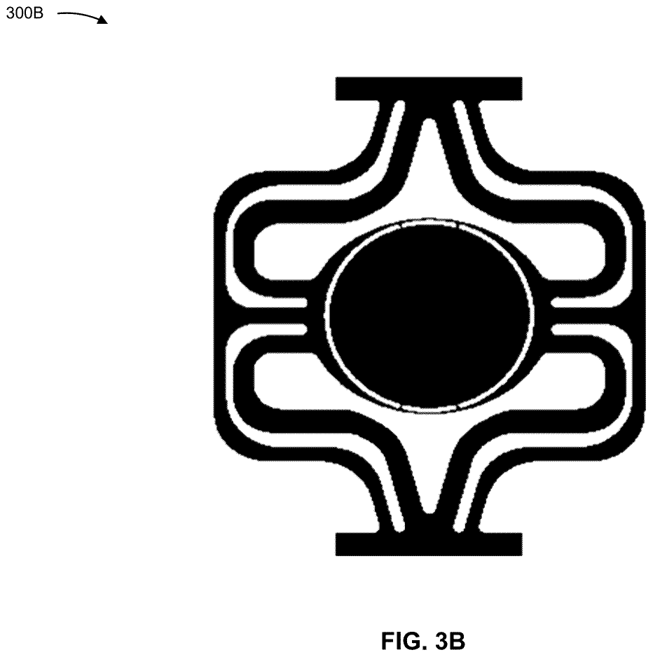

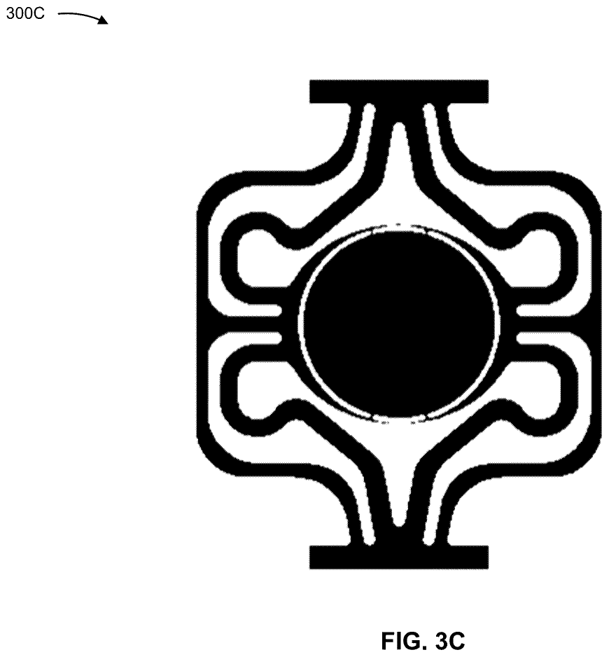

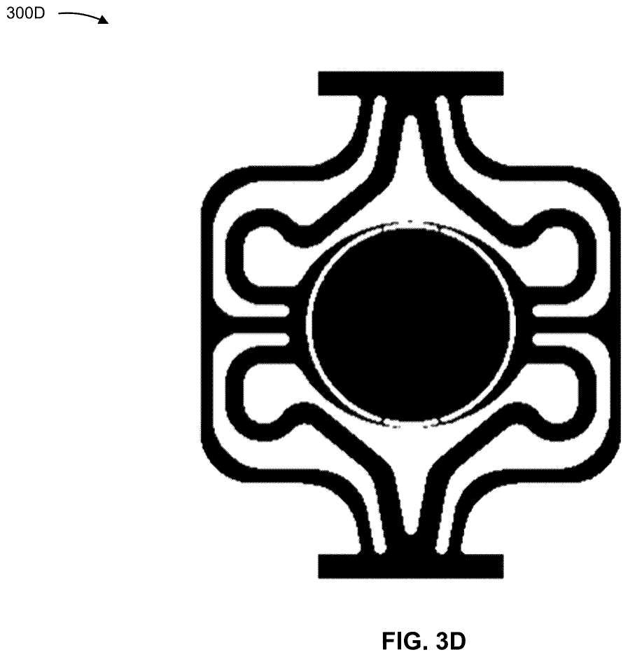

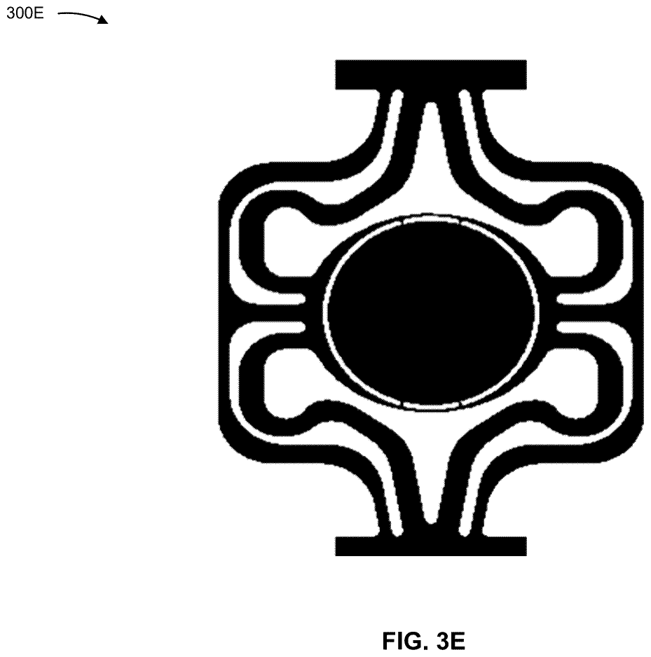

FIGS. 3A-3E show MEMS devices 300A-300E with alternative design configurations. The MEMS devices 300A-300E may be similar to the MEMS device 200 described in connection with FIGS. 2A-2E, except with differently shaped suspension beams.

In FIG. 3A, the suspension assembly of the MEMS device 300A includes outer and inner suspension beams that have a majority section formed in an arc-shape.

In FIG. 3B, the suspension assembly of the MEMS device 300B includes outer and inner suspension beams that have each have three or more sections, with each section having a constant width.

In FIG. 3C, the suspension assembly of the MEMS device 300C includes outer and inner suspension beams that have each have three or more sections, with each section having a nonconstant width. The sections may be straight or circular.

In FIG. 3D, the suspension assembly of the MEMS device 300D includes outer and inner suspension beams that have each have three or more sections, with each section having a nonconstant width. The sections may be straight or circular.

In FIG. 3E, the suspension assembly of the MEMS device 300E includes outer and inner suspension beams that have each have three or more control points. The outer and inner suspension beams may be designed using splines that follow the control points. Each beam may be defined by two splines, with or without constant distance between the two splines.

As indicated above, FIGS. 3A-3E are provided as examples. Other examples may differ from what is described with regard to FIGS. 3A-3E.

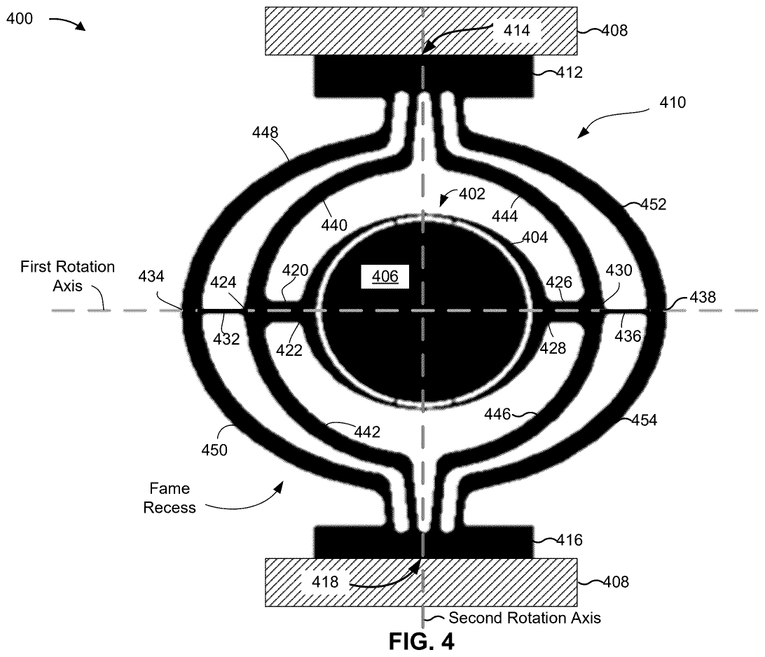

FIG. 4 shows a top view of a MEMS device 400 according to one or more implementations. The MEMS device 400 may be a MEMS mirror device. The MEMS device 400 may include a mirror system 402 including a connector ring 404 and a mirror body 406 coupled to the connector ring 404. The mirror body 406, arranged inside the connector ring 404, is configured to rotate about a first rotation axis (e.g., a fast axis) and rotate about a second rotation axis (e.g., a slow axis) that is perpendicular to the first rotation axis. The mirror system 402 (e.g., the connector ring 404 and the mirror body 406) may be configured to oscillate about the first rotation axis at a first frequency and oscillate about the second rotation axis at a second frequency that is lower than the first frequency. A frame 408 is provided that is rotationally fixed. The frame 408 may include or otherwise define a frame recess over which the mirror system 402 is suspended.

The MEMS device 400 may further include a suspension assembly 410 that is mechanically coupled to and between the mirror system 402 and the frame 408. The suspension assembly 410 may suspend the mirror system 402 over the frame recess. The suspension assembly 410 may include a first anchor assembly 412 attached to the frame at a first frame attachment point 414 arranged on the second rotation axis. The suspension assembly 410 may further include a second anchor assembly 416 attached to the frame at a second frame attachment point 418 arranged on the second rotation axis. The first frame attachment point 414 and the second frame attachment point 418 may be arranged on opposite sides of the mirror body 406 along the second rotation axis. The suspension assembly 410 may further include a first inner torsion beam 420 coupled to the connector ring 404 at a first mirror attachment point 422 arranged on the first axis. The first inner torsion beam 420 may extend from the first mirror attachment point 422 away from the connector ring 404 along the first rotation axis to a first inner suspension beam attachment point 424. The suspension assembly 410 may further include a second inner torsion beam 426 coupled to the connector ring 404 at a second mirror attachment point 428 arranged on the first axis. The second inner torsion beam 426 may extend from the second mirror attachment point 428 away from the connector ring 404 along the first rotation axis to a second inner suspension beam attachment point 430. The first mirror attachment point 422 and the second mirror attachment point 428 may be arranged on opposite sides of the mirror body 406 along the first rotation axis.

The suspension assembly 410 may further include a first outer torsion beam 432 coupled to the first inner suspension beam attachment point 424. The first outer torsion beam 432 extends from the first inner suspension beam attachment point 424 away from the connector ring 404 along the first rotation axis to a first outer suspension beam attachment point 434. The suspension assembly 410 may further include a second outer torsion beam 436 coupled to the second inner suspension beam attachment point 430. The second outer torsion beam 436 may extend from the second inner suspension beam attachment point 430 away from the connector ring 404 along the first rotation axis to a second outer suspension beam attachment point 438.

The suspension assembly 410 may further include a first pair of inner suspension beams connected to the first inner suspension beam attachment point 424. The first pair of outer suspension beams may extend from the first inner suspension beam attachment point 424 and connect to the first anchor assembly 412 and to the second anchor assembly 416, respectively. The first pair of inner suspension beams may include a first inner suspension beam 440 that is attached to the first inner suspension beam attachment point 424 and to the first anchor assembly 412, and a second inner suspension beam 442 that is attached to the first inner suspension beam attachment point 424 and to the second anchor assembly 416.

The suspension assembly 410 may further include a second pair of inner suspension beams connected to the second inner suspension beam attachment point 430. The second pair of outer suspension beams may extend from the second inner suspension beam attachment point 430 and connect to the first anchor assembly 412 and to the second anchor assembly 416, respectively. The second pair of inner suspension beams may include a third inner suspension beam 444 that is attached to the second inner suspension beam attachment point 430 and to the first anchor assembly 412, and a fourth inner suspension beam 446 that is attached to the second inner suspension beam attachment point 430 and to the second anchor assembly 416.

The suspension assembly 410 may further include a first pair of outer suspension beams connected to the first outer suspension beam attachment point 434. The first pair of outer suspension beams may extend from the first outer suspension beam attachment point 434 and connect to the first anchor assembly 412 and to the second anchor assembly 416, respectively. The first pair of outer suspension beams may include a first outer suspension beam 448 that is attached to the first outer suspension beam attachment point 434 and to the first anchor assembly 412, and a second outer suspension beam 450 that is attached to the first outer suspension beam attachment point 434 and to the second anchor assembly 416.

The suspension assembly 410 may further include a second pair of outer suspension beams connected to the second outer suspension beam attachment point 438. The second pair of outer suspension beams may extend from the second outer suspension beam attachment point 438 and connect to the first anchor assembly 412 and to the second anchor assembly 416, respectively. The second pair of outer suspension beams may include a third outer suspension beam 452 that is attached to the second outer suspension beam attachment point 438 and to the first anchor assembly 412, and a fourth outer suspension beam 454 that is attached to the second outer suspension beam attachment point 438 and to the second anchor assembly 416

The suspension beams may be designed to enable the mirror body to oscillate about the first rotation axis at a first frequency and oscillate about the second rotation axis at a second frequency that is lower than the first frequency.

In addition, the first outer suspension beam 448, the second outer suspension beam 450, the first inner suspension beam 440, the second inner suspension beam 442 may be configured to be displaced, in-phase, about the second rotation axis. Additionally, the third outer suspension beam 452, the fourth outer suspension beam 454, the third inner suspension beam 444, the fourth inner suspension beam 446 may be configured to be displaced, in-phase, about the second rotation axis, and out-of-phase about the second rotation axis relative to the first outer suspension beam 448, the second outer suspension beam 450, the first inner suspension beam 440, the second inner suspension beam 442. Thus, the mode with out-of-phase rotation of inner beams with respect to outer beams around second rotation axis can be exploited (e.g., main mode targeted: in-phase rotation of inner beams with respect to outer beams around second rotation axis). Additionally, the first outer suspension beam 448, the third outer suspension beam 452, the first inner suspension beam 440, the third inner suspension beam 444 may be configured to be displaced, in-phase, about the first rotation axis. Additionally, the second outer suspension beam 450, the fourth outer suspension beam 454, the second inner suspension beam 442, the fourth inner suspension beam 446 may be configured to be displaced, in-phase, about the first rotation axis, and out-of-phase about the first rotation axis relative to the first outer suspension beam 448, the third outer suspension beam 452, the first inner suspension beam 440, the third inner suspension beam 444. Thus, the mode with out-of-phase rotation of inner beams with respect to outer beams around first rotation axis can be exploited (e.g., main mode targeted: in-phase rotation of inner beams with respect to outer beams around first rotation axis).

The suspension assembly 410 may further include a plurality of piezoelectric actuators coupled to a plurality of suspension beams, as similarly illustrated in and described in connection with FIG. 2C. The plurality of suspension beams including the first pair of inner suspension beams, the second pair of inner suspension beams, the first pair of outer suspension beams, and the second pair of outer suspension beams. Each piezoelectric actuator of the plurality of piezoelectric actuators may be coupled to a respective suspension beam of the plurality of suspension beams to induce a deformation of the respective suspension beam. Additionally, an actuation circuit may generate actuation signals, and provide the actuation signals to the plurality of piezoelectric actuators to control deformations of the plurality of suspension beams for actuating rotations of the mirror body about the first rotation axis and the second rotation axis.

The suspension assembly 410 may further include a plurality of piezoelectric sensors coupled to the plurality of suspension beams, as similarly illustrated in and described in connection with FIG. 2C. The plurality of piezoelectric sensors may sense the deformations of the plurality of suspension beams and generate corresponding sensor signals. The actuation circuit may adjust an actuation of the plurality of piezoelectric actuators based on the corresponding sensor signals to regulate movements of the mirror body about the first rotation axis and the second rotation axis.

As indicated above, FIG. 4 is provided as an example. Other examples may differ from what is described with regard to FIG. 4.

The following provides an overview of some Aspects of the present disclosure:
Aspect 1: A MEMS device, comprising: a mirror system including a connector ring and a mirror body coupled to the connector ring, wherein the mirror body, arranged inside the connector ring, is configured to rotate about a first rotation axis and to rotate about a second rotation axis that is perpendicular to the first rotation axis; a frame that is rotationally fixed, the frame comprising a frame recess over which the mirror system is suspended; and a suspension assembly mechanically coupled to and between the mirror system and the frame, the suspension assembly configured to suspend the mirror system over the frame recess, wherein the suspension assembly comprises: a first anchor assembly attached to the frame at a first frame attachment point arranged on the second rotation axis; a second anchor assembly attached to the frame at a second frame attachment point arranged on the second rotation axis, wherein the first frame attachment point and the second frame attachment point are arranged on opposite sides of the mirror body along the second rotation axis; a first torsion beam coupled to the connector ring at a first mirror attachment point arranged on the first rotation axis, wherein the first torsion beam extends from the first mirror attachment point away from the connector ring along the first rotation axis to a first suspension beam attachment point; a second torsion beam coupled to the connector ring at a second mirror attachment point arranged on the first rotation axis, wherein the second torsion beam extends from the second mirror attachment point away from the connector ring along the first rotation axis to a second suspension beam attachment point, and wherein the first mirror attachment point and the second mirror attachment point are arranged on opposite sides of the mirror body along the first rotation axis; a first pair of outer suspension beams connected to the first suspension beam attachment point, wherein the first pair of outer suspension beams extend from the first suspension beam attachment point and connect to the first anchor assembly and to the second anchor assembly, respectively; a second pair of outer suspension beams connected to the second suspension beam attachment point, wherein the second pair of outer suspension beams extend from the second suspension beam attachment point and connect to the first anchor assembly and to the second anchor assembly, respectively; a first inner suspension beam connected to the first anchor assembly and the connector ring; a second inner suspension beam connected to the second anchor assembly and the connector ring; a third inner suspension beam connected to the first anchor assembly and the connector ring; and a fourth inner suspension beam connected to the second anchor assembly and the connector ring.
Aspect 2: The MEMS device of Aspect 1, wherein the first pair of outer suspension beams comprises: a first outer suspension beam that is attached to the first suspension beam attachment point and to the first anchor assembly; and a second outer suspension beam that is attached to the first suspension beam attachment point and to the second anchor assembly, and wherein the second pair of outer suspension beams comprises: a third outer suspension beam that is attached to the second suspension beam attachment point and to the first anchor assembly; and a fourth outer suspension beam that is attached to the second suspension beam attachment point and to the second anchor assembly.
Aspect 3: The MEMS device of Aspect 2, wherein the first inner suspension beam is arranged between the first outer suspension beam and the mirror system, wherein the second inner suspension beam is arranged between the second outer suspension beam and the mirror system, wherein the third inner suspension beam is arranged between the third outer suspension beam and the mirror system, and wherein the fourth inner suspension beam is arranged between the fourth outer suspension beam and the mirror system.
Aspect 4: The MEMS device of Aspect 2, wherein the first torsion beam, the first inner suspension beam, and the second inner suspension beam are attached to the connector ring on a first lateral side of the connector ring, and wherein the second torsion beam, the third inner suspension beam, and the fourth inner suspension beam are attached to the connector ring on a second lateral side of the connector ring opposite to the first lateral side.
Aspect 5: The MEMS device of Aspect 4, wherein the first inner suspension beam includes a first torsion bar section that extends parallel to the first torsion beam and is attached to the connector ring, wherein the second inner suspension beam includes a second torsion bar section that extends parallel to the first torsion beam and is attached to the connector ring, wherein the third inner suspension beam includes a third torsion bar section that extends parallel to the second torsion beam and is attached to the connector ring, and wherein the fourth inner suspension beam includes a fourth torsion bar section that extends parallel to the second torsion beam and is attached to the connector ring.
Aspect 6: The MEMS device of Aspect 2, wherein the first outer suspension beam, the third outer suspension beam, the first inner suspension beam, and the third inner suspension beam have parallel end sections that are attached to the first anchor assembly, the parallel end sections being parallel to the second rotation axis.
Aspect 7: The MEMS device of Aspect 2, wherein the second outer suspension beam, the fourth outer suspension beam, the second inner suspension beam, and the fourth inner suspension beam have parallel end sections that are attached to the second anchor assembly, the parallel end sections being parallel to the second rotation axis.
Aspect 8: The MEMS device of Aspect 2, wherein the first outer suspension beam, the third outer suspension beam, the first inner suspension beam, and the third inner suspension beam have end sections that are attached to the first anchor assembly at an angle of 0° to 10° relative to the second rotation axis.
Aspect 9: The MEMS device of Aspect 8, wherein the first inner suspension beam and the third inner suspension beam are connected together at the first anchor assembly in a V-shape.
Aspect 10: The MEMS device of Aspect 2, wherein the second outer suspension beam, the fourth outer suspension beam, the second inner suspension beam, and the fourth inner suspension beam have end sections that are attached to the second anchor assembly at an angle of 0° to 10° relative to the second rotation axis.
Aspect 11: The MEMS device of Aspect 10, wherein the second inner suspension beam and the fourth inner suspension beam are connected together at the second anchor assembly in a V-shape.
Aspect 12: The MEMS device of Aspect 2, wherein the first outer suspension beam, the third outer suspension beam, the first inner suspension beam, and the third inner suspension beam have first end sections that are attached to the first anchor assembly, wherein the second outer suspension beam, the fourth outer suspension beam, the second inner suspension beam, and the fourth inner suspension beam have second end sections that are attached to the second anchor assembly, wherein the first anchor assembly includes a first notch that extends along the second rotation axis between the first end sections of the first inner suspension beam and the third inner suspension beam, and wherein the second anchor assembly includes a second notch that extends along the second rotation axis between the second end sections of the second inner suspension beam and the fourth inner suspension beam.
Aspect 13: The MEMS device of Aspect 12, wherein the first notch and the second notch are configured to reduce stress for rotation of the suspension assembly about the second rotation axis.
Aspect 14: The MEMS device of Aspect 2, further comprising: a plurality of piezoelectric actuators coupled to a plurality of suspension beams, the plurality of suspension beams including the first outer suspension beam, the second outer suspension beam, the third outer suspension beam, the fourth outer suspension beam, the first inner suspension beam, the second inner suspension beam, the third inner suspension beam, and the fourth inner suspension beam, wherein each piezoelectric actuator of the plurality of piezoelectric actuators is coupled to a respective suspension beam of the plurality of suspension beams to induce a deformation of the respective suspension beam; and an actuation circuit configured to generate actuation signals, and provide the actuation signals to the plurality of piezoelectric actuators to control deformations of the plurality of suspension beams for actuating rotations of the mirror body about the first rotation axis and the second rotation axis.
Aspect 15: The MEMS device of Aspect 2, wherein the first outer suspension beam, the second outer suspension beam, the first inner suspension beam, the second inner suspension beam are configured to be displaced, in-phase, about the second rotation axis, wherein the third outer suspension beam, the fourth outer suspension beam, the third inner suspension beam, the fourth inner suspension beam are configured to be displaced, in-phase, about the second rotation axis, and out-of-phase about the second rotation axis relative to the first outer suspension beam, the second outer suspension beam, the first inner suspension beam, the second inner suspension beam, wherein the first outer suspension beam, the third outer suspension beam, the first inner suspension beam, the third inner suspension beam are configured to be displaced, in-phase, about the first rotation axis, and wherein the second outer suspension beam, the fourth outer suspension beam, the second inner suspension beam, the fourth inner suspension beam are configured to be displaced, in-phase, about the first rotation axis, and out-of-phase about the first rotation axis relative to the first outer suspension beam, the third outer suspension beam, the first inner suspension beam, the third inner suspension beam.
Aspect 16: The MEMS device of any of Aspects 1-15, further comprising: a plurality of piezoelectric actuators coupled to suspension beams of the suspension assembly, the plurality of piezoelectric actuators configured to induce deformations of the suspension beams to cause the mirror body to rotate about the first rotation axis and the second rotation axis.
Aspect 17: The MEMS device of Aspect 16, further comprising: an actuation circuit configured to generate actuation signals, and provide the actuation signals to the plurality of piezoelectric actuators to control the deformations of the suspension beams.
Aspect 18: The MEMS device of Aspect 17, further comprising: a plurality of piezoelectric sensors coupled to the suspension beams, the plurality of piezoelectric sensors configured to sense the deformations of the suspension beams and generate corresponding sensor signals, wherein the actuation circuit is configured to adjust an actuation of the plurality of piezoelectric actuators based on the corresponding sensor signals to regulate movements of the mirror body about the first rotation axis and the second rotation axis.
Aspect 19: The MEMS device of any of Aspects 1-18, wherein the mirror body is configured to oscillate about the first rotation axis at a first frequency and to oscillate about the second rotation axis at a second frequency that is lower than the first frequency.
Aspect 20: The MEMS device of Aspect 19, wherein each suspension beam of the first pair of outer suspension beams, the second pair of outer suspension beams, the first inner suspension beam, the second inner suspension beam, the third inner suspension beam, and the fourth inner suspension beam is respectively shaped to tune the first frequency, the second frequency, a maximum tilt amplitude about the first rotation axis, and a maximum tilt amplitude about the second rotation axis.
Aspect 21: The MEMS device of any of Aspects 1-20, wherein each suspension beam of the first inner suspension beam, the second inner suspension beam, the third inner suspension beam, and the fourth inner suspension beam has three or more curved sections.
Aspect 22: The MEMS device of any of Aspects 1-21, wherein a shape of each suspension beam of the first inner suspension beam, the second inner suspension beam, the third inner suspension beam, and the fourth inner suspension beam is defined by two splines.
Aspect 23: The MEMS device of any of Aspects 1-22, further comprising: a plurality of suspension beams (springs) coupled to the frame and the connector ring such that the mirror body is displaceable about the first rotation axis and the second rotation axis via deformations of the plurality of suspension beams; and a plurality of piezoelectric actuators coupled to the plurality of suspension beams, wherein each piezoelectric actuator is coupled to a respective suspension spring of the plurality of suspension beams to induce a deformation of the respective suspension spring.
Aspect 24: The MEMS device of any of Aspects 1-23, wherein each outer suspension beam of the plurality of suspension beams is coupled to at least two piezoelectric actuators of the plurality of piezoelectric actuators, the at least two piezoelectric actuators configured to induce deformation of the coupled outer suspension spring.
Aspect 25: The MEMS device of any of Aspects 1-24, wherein the actuation circuit is configured to control the deformations of the plurality of suspension springs via the actuation signals to induce movements of the mirror body about the first rotation axis and the second rotation axis.
Aspect 26: The MEMS device of any of Aspects 1-25, further comprising: a plurality of suspension beams coupled to the frame and the connector ring, the plurality of suspension beams configured to undergo deformations to induce movements of the mirror body about the first rotation axis and the second rotation axis; a plurality of piezoelectric actuators coupled to the plurality of suspension beams, wherein each piezoelectric actuator is coupled to a respective suspension beam of the plurality of suspension beams to induce a deformation of the respective suspension beam; and an actuation circuit configured to generate actuation signals for actuating the plurality of piezoelectric actuators.
Aspect 27: A MEMS device, comprising: a mirror system including a connector ring and a mirror body coupled to the connector ring, wherein the mirror body, arranged inside the connector ring, is configured to rotate about a first rotation axis and rotate about a second rotation axis that is perpendicular to the first rotation axis; a frame that is rotationally fixed, the frame comprising a frame recess over which the mirror system is suspended; and a suspension assembly mechanically coupled to and between the mirror system and the frame, the suspension assembly configured to suspend the mirror system over the frame recess, wherein the suspension assembly comprises: a first anchor assembly attached to the frame at a first frame attachment point arranged on the second rotation axis; a second anchor assembly attached to the frame at a second frame attachment point arranged on the second rotation axis, wherein the first frame attachment point and the second frame attachment point are arranged on opposite sides of the mirror body along the second rotation axis; a first inner torsion beam coupled to the connector ring at a first mirror attachment point arranged on the first rotation axis, wherein the first inner torsion beam extends from the first mirror attachment point away from the connector ring along the first rotation axis to a first inner suspension beam attachment point; a second inner torsion beam coupled to the connector ring at a second mirror attachment point arranged on the first rotation axis, wherein the second inner torsion beam extends from the second mirror attachment point away from the connector ring along the first rotation axis to a second inner suspension beam attachment point, and wherein the first mirror attachment point and the second mirror attachment point are arranged on opposite sides of the mirror body along the first rotation axis; a first outer torsion beam coupled to the first inner suspension beam attachment point, wherein the first outer torsion beam extends from the first inner suspension beam attachment point away from the connector ring along the first rotation axis to a first outer suspension beam attachment point; a second outer torsion beam coupled to the second inner suspension beam attachment point, wherein the second outer torsion beam extends from the second inner suspension beam attachment point away from the connector ring along the first rotation axis to a second outer suspension beam attachment point; a first pair of inner suspension beams connected to the first inner suspension beam attachment point, wherein the first pair of outer suspension beams extend from the first inner suspension beam attachment point and connect to the first anchor assembly and to the second anchor assembly, respectively; a second pair of inner suspension beams connected to the second inner suspension beam attachment point, wherein the second pair of outer suspension beams extend from the second inner suspension beam attachment point and connect to the first anchor assembly and to the second anchor assembly, respectively; a first pair of outer suspension beams connected to the first outer suspension beam attachment point, wherein the first pair of outer suspension beams extend from the first outer suspension beam attachment point and connect to the first anchor assembly and to the second anchor assembly, respectively; and a second pair of outer suspension beams connected to the second outer suspension beam attachment point, wherein the second pair of outer suspension beams extend from the second outer suspension beam attachment point and connect to the first anchor assembly and to the second anchor assembly, respectively.
Aspect 28: The MEMS device of Aspect 27, wherein the first pair of inner suspension beams comprises: a first inner suspension beam that is attached to the first inner suspension beam attachment point and to the first anchor assembly; and a second inner suspension beam that is attached to the first inner suspension beam attachment point and to the second anchor assembly, wherein the second pair of inner suspension beams comprises: a third inner suspension beam that is attached to the second inner suspension beam attachment point and to the first anchor assembly; and a fourth inner suspension beam that is attached to the second inner suspension beam attachment point and to the second anchor assembly, wherein the first pair of outer suspension beams comprises: a first outer suspension beam that is attached to the first outer suspension beam attachment point and to the first anchor assembly; and a second outer suspension beam that is attached to the first outer suspension beam attachment point and to the second anchor assembly, and wherein the second pair of outer suspension beams comprises: a third outer suspension beam that is attached to the second outer suspension beam attachment point and to the first anchor assembly; and a fourth outer suspension beam that is attached to the second outer suspension beam attachment point and to the second anchor assembly.
Aspect 29: The MEMS device of Aspect 28, wherein the first outer suspension beam, the second outer suspension beam, the first inner suspension beam, the second inner suspension beam are configured to be displaced, in-phase, about the second rotation axis, wherein the third outer suspension beam, the fourth outer suspension beam, the third inner suspension beam, the fourth inner suspension beam are configured to be displaced, in-phase, about the second rotation axis, and out-of-phase about the second rotation axis relative to the first outer suspension beam, the second outer suspension beam, the first inner suspension beam, the second inner suspension beam, wherein the first outer suspension beam, the third outer suspension beam, the first inner suspension beam, the third inner suspension beam are configured to be displaced, in-phase, about the first rotation axis, and wherein the second outer suspension beam, the fourth outer suspension beam, the second inner suspension beam, the fourth inner suspension beam are configured to be displaced, in-phase, about the first rotation axis, and out-of-phase about the first rotation axis relative to the first outer suspension beam, the third outer suspension beam, the first inner suspension beam, the third inner suspension beam.
Aspect 30: The MEMS device of any of Aspects 27-29, further comprising: a plurality of piezoelectric actuators coupled to a plurality of suspension beams, the plurality of suspension beams including the first pair of inner suspension beams, the second pair of inner suspension beams, the first pair of outer suspension beams, and the second pair of outer suspension beams, wherein each piezoelectric actuator of the plurality of piezoelectric actuators is coupled to a respective suspension beam of the plurality of suspension beams to induce a deformation of the respective suspension beam; and an actuation circuit configured to generate actuation signals, and provide the actuation signals to the plurality of piezoelectric actuators to control deformations of the plurality of suspension beams for actuating rotations of the mirror body about the first rotation axis and the second rotation axis.
Aspect 31: The MEMS device of Aspect 30, further comprising: a plurality of piezoelectric sensors coupled to the plurality of suspension beams, the plurality of piezoelectric sensors configured to sense the deformations of the plurality of suspension beams and generate corresponding sensor signals, wherein the actuation circuit is configured to adjust an actuation of the plurality of piezoelectric actuators based on the corresponding sensor signals to regulate movements of the mirror body about the first rotation axis and the second rotation axis.
Aspect 32: The MEMS device of any of Aspects 27-31, wherein the mirror body is configured to oscillate about the first rotation axis at a first frequency and oscillate about the second rotation axis at a second frequency that is lower than the first frequency.
Aspect 33: A system configured to perform one or more operations recited in one or more of Aspects 1-32.
Aspect 34: An apparatus comprising means for performing one or more operations recited in one or more of Aspects 1-32.
Aspect 35: A non-transitory computer-readable medium storing a set of instructions, the set of instructions comprising one or more instructions that, when executed by a device, cause the device to perform one or more operations recited in one or more of Aspects 1-32.
Aspect 36: A computer program product comprising instructions or code for executing one or more operations recited in one or more of Aspects 1-32.

The foregoing disclosure provides illustration and description, but is not intended to be exhaustive or to limit the implementations to the precise form disclosed. Modifications and variations may be made in light of the above disclosure or may be acquired from practice of the implementations.

For example, although implementations described herein relate to MEMS devices with a mirror, it is to be understood that other implementations may include optical devices other than MEMS mirror devices or other MEMS oscillating structures. In addition, although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer, or an electronic circuit.

Some implementations may be described herein in connection with thresholds. As used herein, “satisfying” a threshold may refer to a value being greater than the threshold, more than the threshold, higher than the threshold, greater than or equal to the threshold, less than the threshold, fewer than the threshold, lower than the threshold, less than or equal to the threshold, equal to the threshold, or the like.

As used herein, the term “component” is intended to be broadly construed as hardware, firmware, or a combination of hardware and software. It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code—it being understood that software and hardware can be designed to implement the systems and/or methods based on the description herein.

Any of the processing components may be implemented as a central processing unit (CPU) or other processor reading and executing a software program from a non-transitory computer-readable recording medium such as a hard disk or a semiconductor memory device. For example, instructions may be executed by one or more processors, such as one or more CPUs, digital signal processors (DSPs), general-purpose microprocessors, application-specific integrated circuits (ASICs), field programmable logic arrays (FPLAs), programmable logic controller (PLC), or other equivalent integrated or discrete logic circuitry. Accordingly, the term “processor,” as used herein refers to any of the foregoing structures or any other structure suitable for implementation of the techniques described herein. Software may be stored on a non-transitory computer-readable medium such that the non-transitory computer readable medium includes a program code or a program algorithm stored thereon which, when executed, causes the processor, via a computer program, to perform the steps of a method.

A controller including hardware may also perform one or more of the techniques of this disclosure. A controller, including one or more processors, may use electrical signals and digital algorithms to perform its receptive, analytic, and control functions, which may further include corrective functions. Such hardware, software, and firmware may be implemented within the same device or within separate devices to support the various techniques described in this disclosure.

A signal processing circuit and/or a signal conditioning circuit may receive one or more signals (e.g., measurement signals) from one or more components in the form of raw measurement data and may derive, from the measurement signal further information. Signal conditioning, as used herein, refers to manipulating an analog signal in such a way that the signal meets the requirements of a next stage for further processing. Signal conditioning may include converting from analog to digital (e.g., via an analog-to-digital converter), amplification, filtering, converting, biasing, range matching, isolation and any other processes required to make a signal suitable for processing after conditioning.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a and b, a and c, b and c, and a, b, and c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A microelectromechanical system (MEMS) device, comprising:
a mirror system including a connector ring and a mirror body coupled to the connector ring, wherein the mirror body, arranged inside the connector ring, is configured to rotate about a first rotation axis and to rotate about a second rotation axis that is perpendicular to the first rotation axis;
a frame that is rotationally fixed, the frame comprising a frame recess over which the mirror system is suspended; and
a suspension assembly mechanically coupled to and between the mirror system and the frame, the suspension assembly configured to suspend the mirror system over the frame recess,
wherein the suspension assembly comprises:
a first anchor assembly attached to the frame at a first frame attachment point arranged on the second rotation axis;
a second anchor assembly attached to the frame at a second frame attachment point arranged on the second rotation axis, wherein the first frame attachment point and the second frame attachment point are arranged on opposite sides of the mirror body along the second rotation axis;
a first torsion beam coupled to the connector ring at a first mirror attachment point arranged on the first rotation axis, wherein the first torsion beam extends from the first mirror attachment point away from the connector ring along the first rotation axis to a first suspension beam attachment point;
a second torsion beam coupled to the connector ring at a second mirror attachment point arranged on the first rotation axis, wherein the second torsion beam extends from the second mirror attachment point away from the connector ring along the first rotation axis to a second suspension beam attachment point, and wherein the first mirror attachment point and the second mirror attachment point are arranged on opposite sides of the mirror body along the first rotation axis;
a first pair of outer suspension beams connected to the first suspension beam attachment point, wherein the first pair of outer suspension beams extend from the first suspension beam attachment point and connect to the first anchor assembly and to the second anchor assembly, respectively;
a second pair of outer suspension beams connected to the second suspension beam attachment point, wherein the second pair of outer suspension beams extend from the second suspension beam attachment point and connect to the first anchor assembly and to the second anchor assembly, respectively;
a first inner suspension beam connected to the first anchor assembly and the connector ring;
a second inner suspension beam connected to the second anchor assembly and the connector ring;
a third inner suspension beam connected to the first anchor assembly and the connector ring; and
a fourth inner suspension beam connected to the second anchor assembly and the connector ring.

2. The MEMS device of claim 1, wherein the first pair of outer suspension beams comprises:
a first outer suspension beam that is attached to the first suspension beam attachment point and to the first anchor assembly; and
a second outer suspension beam that is attached to the first suspension beam attachment point and to the second anchor assembly, and
wherein the second pair of outer suspension beams comprises:
a third outer suspension beam that is attached to the second suspension beam attachment point and to the first anchor assembly; and
a fourth outer suspension beam that is attached to the second suspension beam attachment point and to the second anchor assembly.

3. The MEMS device of claim 2, wherein the first inner suspension beam is arranged between the first outer suspension beam and the mirror system,
wherein the second inner suspension beam is arranged between the second outer suspension beam and the mirror system,
wherein the third inner suspension beam is arranged between the third outer suspension beam and the mirror system, and
wherein the fourth inner suspension beam is arranged between the fourth outer suspension beam and the mirror system.

4. The MEMS device of claim 2, wherein the first torsion beam, the first inner suspension beam, and the second inner suspension beam are attached to the connector ring on a first lateral side of the connector ring, and
wherein the second torsion beam, the third inner suspension beam, and the fourth inner suspension beam are attached to the connector ring on a second lateral side of the connector ring opposite to the first lateral side.

5. The MEMS device of claim 4, wherein the first inner suspension beam includes a first torsion bar section that extends parallel to the first torsion beam and is attached to the connector ring,
wherein the second inner suspension beam includes a second torsion bar section that extends parallel to the first torsion beam and is attached to the connector ring,
wherein the third inner suspension beam includes a third torsion bar section that extends parallel to the second torsion beam and is attached to the connector ring, and
wherein the fourth inner suspension beam includes a fourth torsion bar section that extends parallel to the second torsion beam and is attached to the connector ring.

6. The MEMS device of claim 2, wherein the first outer suspension beam, the third outer suspension beam, the first inner suspension beam, and the third inner suspension beam have parallel end sections that are attached to the first anchor assembly, the parallel end sections being parallel to the second rotation axis.

7. The MEMS device of claim 2, wherein the second outer suspension beam, the fourth outer suspension beam, the second inner suspension beam, and the fourth inner suspension beam have parallel end sections that are attached to the second anchor assembly, the parallel end sections being parallel to the second rotation axis.

8. The MEMS device of claim 2, wherein the first outer suspension beam, the third outer suspension beam, the first inner suspension beam, and the third inner suspension beam have end sections that are attached to the first anchor assembly at an angle of 0° to 10° relative to the second rotation axis.

9. The MEMS device of claim 8, wherein the first inner suspension beam and the third inner suspension beam are connected together at the first anchor assembly in a V-shape.

10. The MEMS device of claim 2, wherein the second outer suspension beam, the fourth outer suspension beam, the second inner suspension beam, and the fourth inner suspension beam have end sections that are attached to the second anchor assembly at an angle of 0° to 10° relative to the second rotation axis.

11. The MEMS device of claim 10, wherein the second inner suspension beam and the fourth inner suspension beam are connected together at the second anchor assembly in a V-shape.

12. The MEMS device of claim 2, wherein the first outer suspension beam, the third outer suspension beam, the first inner suspension beam, and the third inner suspension beam have first end sections that are attached to the first anchor assembly,
wherein the second outer suspension beam, the fourth outer suspension beam, the second inner suspension beam, and the fourth inner suspension beam have second end sections that are attached to the second anchor assembly,
wherein the first anchor assembly includes a first notch that extends along the second rotation axis between the first end sections of the first inner suspension beam and the third inner suspension beam, and
wherein the second anchor assembly includes a second notch that extends along the second rotation axis between the second end sections of the second inner suspension beam and the fourth inner suspension beam.

13. The MEMS device of claim 12, wherein the first notch and the second notch are configured to reduce stress for rotation of the suspension assembly about the second rotation axis.

14. The MEMS device of claim 2, further comprising:
a plurality of piezoelectric actuators coupled to a plurality of suspension beams, the plurality of suspension beams including the first outer suspension beam, the second outer suspension beam, the third outer suspension beam, the fourth outer suspension beam, the first inner suspension beam, the second inner suspension beam, the third inner suspension beam, and the fourth inner suspension beam,
wherein each piezoelectric actuator of the plurality of piezoelectric actuators is coupled to a respective suspension beam of the plurality of suspension beams to induce a deformation of the respective suspension beam; and
an actuation circuit configured to generate actuation signals, and provide the actuation signals to the plurality of piezoelectric actuators to control deformations of the plurality of suspension beams for actuating rotations of the mirror body about the first rotation axis and the second rotation axis.

15. The MEMS device of claim 2, wherein the first outer suspension beam, the second outer suspension beam, the first inner suspension beam, the second inner suspension beam are configured to be displaced, in-phase, about the second rotation axis,
wherein the third outer suspension beam, the fourth outer suspension beam, the third inner suspension beam, the fourth inner suspension beam are configured to be displaced, in-phase, about the second rotation axis, and out-of-phase about the second rotation axis relative to the first outer suspension beam, the second outer suspension beam, the first inner suspension beam, the second inner suspension beam,
wherein the first outer suspension beam, the third outer suspension beam, the first inner suspension beam, the third inner suspension beam are configured to be displaced, in-phase, about the first rotation axis, and
wherein the second outer suspension beam, the fourth outer suspension beam, the second inner suspension beam, the fourth inner suspension beam are configured to be displaced, in-phase, about the first rotation axis, and out-of-phase about the first rotation axis relative to the first outer suspension beam, the third outer suspension beam, the first inner suspension beam, the third inner suspension beam.

16. The MEMS device of claim 1, further comprising:
a plurality of piezoelectric actuators coupled to suspension beams of the suspension assembly, the plurality of piezoelectric actuators configured to induce deformations of the suspension beams to cause the mirror body to rotate about the first rotation axis and the second rotation axis.

17. The MEMS device of claim 16, further comprising:
an actuation circuit configured to generate actuation signals, and provide the actuation signals to the plurality of piezoelectric actuators to control the deformations of the suspension beams.

18. The MEMS device of claim 17, further comprising:
a plurality of piezoelectric sensors coupled to the suspension beams, the plurality of piezoelectric sensors configured to sense the deformations of the suspension beams and generate corresponding sensor signals,
wherein the actuation circuit is configured to adjust an actuation of the plurality of piezoelectric actuators based on the corresponding sensor signals to regulate movements of the mirror body about the first rotation axis and the second rotation axis.

19. The MEMS device of claim 1, wherein the mirror body is configured to oscillate about the first rotation axis at a first frequency and to oscillate about the second rotation axis at a second frequency that is lower than the first frequency.

20. The MEMS device of claim 19, wherein each suspension beam of the first pair of outer suspension beams, the second pair of outer suspension beams, the first inner suspension beam, the second inner suspension beam, the third inner suspension beam, and the fourth inner suspension beam is respectively shaped to tune the first frequency, the second frequency, a maximum tilt amplitude about the first rotation axis, and a maximum tilt amplitude about the second rotation axis.

21. The MEMS device of claim 1, wherein each suspension beam of the first inner suspension beam, the second inner suspension beam, the third inner suspension beam, and the fourth inner suspension beam has three or more curved sections.

22. The MEMS device of claim 1, wherein a shape of each suspension beam of the first inner suspension beam, the second inner suspension beam, the third inner suspension beam, and the fourth inner suspension beam is defined by two splines.

23. A microelectromechanical system (MEMS) device, comprising:
a mirror system including a connector ring and a mirror body coupled to the connector ring, wherein the mirror body, arranged inside the connector ring, is configured to rotate about a first rotation axis and rotate about a second rotation axis that is perpendicular to the first rotation axis;
a frame that is rotationally fixed, the frame comprising a frame recess over which the mirror system is suspended; and
a suspension assembly mechanically coupled to and between the mirror system and the frame, the suspension assembly configured to suspend the mirror system over the frame recess,
wherein the suspension assembly comprises:
a first anchor assembly attached to the frame at a first frame attachment point arranged on the second rotation axis;
a second anchor assembly attached to the frame at a second frame attachment point arranged on the second rotation axis, wherein the first frame attachment point and the second frame attachment point are arranged on opposite sides of the mirror body along the second rotation axis;
a first inner torsion beam coupled to the connector ring at a first mirror attachment point arranged on the first rotation axis, wherein the first inner torsion beam extends from the first mirror attachment point away from the connector ring along the first rotation axis to a first inner suspension beam attachment point;
a second inner torsion beam coupled to the connector ring at a second mirror attachment point arranged on the first rotation axis, wherein the second inner torsion beam extends from the second mirror attachment point away from the connector ring along the first rotation axis to a second inner suspension beam attachment point, and wherein the first mirror attachment point and the second mirror attachment point are arranged on opposite sides of the mirror body along the first rotation axis;
a first outer torsion beam coupled to the first inner suspension beam attachment point, wherein the first outer torsion beam extends from the first inner suspension beam attachment point away from the connector ring along the first rotation axis to a first outer suspension beam attachment point;
a second outer torsion beam coupled to the second inner suspension beam attachment point, wherein the second outer torsion beam extends from the second inner suspension beam attachment point away from the connector ring along the first rotation axis to a second outer suspension beam attachment point;
a first pair of inner suspension beams connected to the first inner suspension beam attachment point, wherein the first pair of outer suspension beams extend from the first inner suspension beam attachment point and connect to the first anchor assembly and to the second anchor assembly, respectively;
a second pair of inner suspension beams connected to the second inner suspension beam attachment point, wherein the second pair of outer suspension beams extend from the second inner suspension beam attachment point and connect to the first anchor assembly and to the second anchor assembly, respectively;
a first pair of outer suspension beams connected to the first outer suspension beam attachment point, wherein the first pair of outer suspension beams extend from the first outer suspension beam attachment point and connect to the first anchor assembly and to the second anchor assembly, respectively; and
a second pair of outer suspension beams connected to the second outer suspension beam attachment point, wherein the second pair of outer suspension beams extend from the second outer suspension beam attachment point and connect to the first anchor assembly and to the second anchor assembly, respectively.

24. The MEMS device of claim 23, wherein the first pair of inner suspension beams comprises:
a first inner suspension beam that is attached to the first inner suspension beam attachment point and to the first anchor assembly; and
a second inner suspension beam that is attached to the first inner suspension beam attachment point and to the second anchor assembly,
wherein the second pair of inner suspension beams comprises:
a third inner suspension beam that is attached to the second inner suspension beam attachment point and to the first anchor assembly; and
a fourth inner suspension beam that is attached to the second inner suspension beam attachment point and to the second anchor assembly,
wherein the first pair of outer suspension beams comprises:
a first outer suspension beam that is attached to the first outer suspension beam attachment point and to the first anchor assembly; and
a second outer suspension beam that is attached to the first outer suspension beam attachment point and to the second anchor assembly, and
wherein the second pair of outer suspension beams comprises:
a third outer suspension beam that is attached to the second outer suspension beam attachment point and to the first anchor assembly; and
a fourth outer suspension beam that is attached to the second outer suspension beam attachment point and to the second anchor assembly.

25. The MEMS device of claim 24, wherein the first outer suspension beam, the second outer suspension beam, the first inner suspension beam, the second inner suspension beam are configured to be displaced, in-phase, about the second rotation axis,
wherein the third outer suspension beam, the fourth outer suspension beam, the third inner suspension beam, the fourth inner suspension beam are configured to be displaced, in-phase, about the second rotation axis, and out-of-phase about the second rotation axis relative to the first outer suspension beam, the second outer suspension beam, the first inner suspension beam, the second inner suspension beam,
wherein the first outer suspension beam, the third outer suspension beam, the first inner suspension beam, the third inner suspension beam are configured to be displaced, in-phase, about the first rotation axis, and
wherein the second outer suspension beam, the fourth outer suspension beam, the second inner suspension beam, the fourth inner suspension beam are configured to be displaced, in-phase, about the first rotation axis, and out-of-phase about the first rotation axis relative to the first outer suspension beam, the third outer suspension beam, the first inner suspension beam, the third inner suspension beam.

26. The MEMS device of claim 23, further comprising:
a plurality of piezoelectric actuators coupled to a plurality of suspension beams, the plurality of suspension beams including the first pair of inner suspension beams, the second pair of inner suspension beams, the first pair of outer suspension beams, and the second pair of outer suspension beams,
wherein each piezoelectric actuator of the plurality of piezoelectric actuators is coupled to a respective suspension beam of the plurality of suspension beams to induce a deformation of the respective suspension beam; and
an actuation circuit configured to generate actuation signals, and provide the actuation signals to the plurality of piezoelectric actuators to control deformations of the plurality of suspension beams for actuating rotations of the mirror body about the first rotation axis and the second rotation axis.

27. The MEMS device of claim 26, further comprising:
a plurality of piezoelectric sensors coupled to the plurality of suspension beams, the plurality of piezoelectric sensors configured to sense the deformations of the plurality of suspension beams and generate corresponding sensor signals,
wherein the actuation circuit is configured to adjust an actuation of the plurality of piezoelectric actuators based on the corresponding sensor signals to regulate movements of the mirror body about the first rotation axis and the second rotation axis.

28. The MEMS device of claim 23, wherein the mirror body is configured to oscillate about the first rotation axis at a first frequency and oscillate about the second rotation axis at a second frequency that is lower than the first frequency.
